(19) United States
(12) Patent Application Publication
(10) Pub. No.: US 2025/0311516 A1
(43) Pub. Date: Oct. 2, 2025

(54) DISPLAY DEVICE

(71) Applicant: Samsung Display Co., LTD., Yongin-si (KR)

(72) Inventor: Moon Jung AN, Yongin-si (KR)

(21) Appl. No.: 18/965,906

(22) Filed: Dec. 2, 2024

(30) Foreign Application Priority Data
Mar. 28, 2024 (KR) 10-2024-0042357

(51) Int. Cl. H10H 29/85; H10H 29/24

(52) U.S. Cl. CPC H10H 29/857; H10H 29/24

(57) ABSTRACT

A display device includes a pixel including a first subpixel, wherein the first subpixel includes: a first pixel electrode, and a first light emitting element and a second light emitting element on the first pixel electrode, each of the first light emitting element and the second light emitting element including a body portion and a bonding electrode at a first surface of the body portion, the body portion includes a first semiconductor layer, an active layer, and a second semiconductor layer, wherein at least one of the first light emitting element or the second light emitting element is disposed at an angle on the first pixel electrode.

### CROSS-REFERENCE TO RELATED APPLICATION

The present application claims priority to and the benefit of Korean Patent Application No. 10-2024-0042357, filed on Mar. 28, 2024, in the Korean Intellectual Property Office, the entire disclosure of which is incorporated by reference herein.

### BACKGROUND

### 1. Field

Embodiments of the present disclosure relate to a display device.

### 2. Description of the Related Art

As the information society develops, demands for display devices for displaying images are increasing in various forms. Accordingly, various types of display devices including light emitting display devices are being developed. A light emitting display device includes pixels including light emitting elements.

### SUMMARY

Aspects and features of embodiments of the present disclosure provide a display device which can improve the light efficiency of a pixel including a light emitting element.

However, aspects and features of embodiments of the present disclosure are not restricted to the one set forth herein. The above and other aspects and features of the present disclosure will become more apparent to one of ordinary skill in the art to which the present disclosure pertains by referencing the detailed description of the present disclosure given below.

According to one or more embodiments of the present disclosure, there is provided a display device including a pixel including a first subpixel, wherein the first subpixel includes: a first pixel electrode, and a first light emitting element and a second light emitting element on the first pixel electrode, each of the first light emitting element and the second light emitting element including a body portion and a bonding electrode at a first surface of the body portion, the body portion includes a first semiconductor layer, an active layer, and a second semiconductor layer, wherein at least one of the first light emitting element or the second light emitting element is disposed at an angle on the first pixel electrode.

In one or more embodiments, each of the first light emitting element and the second light emitting element may include a light output surface corresponding to a second surface of the body portion.

In one or more embodiments, the light output surfaces of the first light emitting element and the second light emitting element may be tilted toward a center of the first subpixel.

In one or more embodiments, the bonding electrode of each of the first light emitting element and the second light emitting element may be located more on a portion of the first surface of the body portion which is close to the periphery of the first subpixel.

In one or more embodiments, the display device may further include, a light blocking layer around an emission area where the first light emitting element and the second light emitting element are located, and a reflective layer on the light blocking layer.

In one or more embodiments, the light output surfaces of the first light emitting element and the second light emitting element may be tilted toward a periphery of the first subpixel.

In one or more embodiments, the bonding electrode of each of the first light emitting element and the second light emitting element may be located more on a portion of the first surface of the body portion that is close to a center of the first subpixel.

In one or more embodiments, at least one of the bonding electrodes of the first light emitting element or the second light emitting element may have a thickness that gradually changes as a distance to a center or a periphery of the first subpixel decreases.

In one or more embodiments, at least one of the body portions of the first light emitting element or the second light emitting element may be tilted with respect to the first pixel electrode and may contact the first pixel electrode.

In one or more embodiments, the bonding electrode of each of the first light emitting element and the second light emitting element may be on the entire first surface of the body portion.

In one or more embodiments, the first subpixel may further include a third light emitting element on the first pixel electrode and between the first light emitting element and the second light emitting element.

In one or more embodiments, the third light emitting element may include a body portion and a bonding electrode at a first surface of the body portion, the third light emitting element being on and perpendicular to the first pixel electrode, the body portion including a first semiconductor layer, an active layer, and a second semiconductor layer.

In one or more embodiments, the third light emitting element may include a light output surface corresponding to a second surface of the body portion, and the light output surface of the third light emitting element may face toward top of the first subpixel.

In one or more embodiments, the first subpixel may further include a first light conversion layer on the first light emitting element and the second light emitting element.

In one or more embodiments, the first light conversion layer may include first wavelength conversion particles to convert light emitted from the first light emitting element and the second light emitting element into light of another color.

In one or more embodiments, a second surface of the first light conversion layer may include a lens-shaped curved surface.

In one or more embodiments, each of the first light emitting element and the second light emitting element may further include a first reflective layer between the body portion and the bonding electrode.

In one or more embodiments, each of the first light emitting element and the second light emitting element may further include a second reflective layer covering side surfaces of the first semiconductor layer, the active layer, and the second semiconductor layer.

In one or more embodiments, the pixel may further include a second subpixel and a third subpixel, the second subpixel includes a second pixel electrode and at least one light emitting element on the second pixel electrode, and the third subpixel includes a third pixel electrode and at least one light emitting element on the third pixel electrode, the first subpixel, the second subpixel, and the third subpixel being sequentially located along a first direction.

In one or more embodiments, at least one of the first light emitting element or the second light emitting element of the first subpixel may be disposed at an angle on the first pixel electrode to face a center of a unit pixel area where the pixel is located, and the at least one light emitting element of the third subpixel may be located at an angle on the third pixel electrode to face the center of the unit pixel area.

According to one or more embodiments of the present disclosure, there is provided an electronic device for providing an image, including a display device, the display device including a pixel including a first subpixel, wherein the first subpixel includes: a first pixel electrode, and a first light emitting element and a second light emitting element on the first pixel electrode, each of the first light emitting element and the second light emitting element including a body portion and a bonding electrode at a first surface of the body portion, the body portion includes a first semiconductor layer, an active layer, and a second semiconductor layer, wherein at least one of the first light emitting element or the second light emitting element is disposed at an angle on the first pixel electrode.

A display device according to one or more embodiments includes a subpixel including a pixel electrode and a light emitting element disposed at an angle on the pixel electrode. In one or more embodiments, the light emitting element may be tilted toward the center of the subpixel or the center of a pixel including the subpixel or may be tilted toward a reflective layer disposed around the subpixel. According to one or more embodiments, the light efficiency of the subpixel or the pixel can be improved.

However, effects, aspects, and features according to the embodiments of the

present disclosure are not limited to those exemplified above and various other effects, aspects, and features are incorporated herein.

### BRIEF DESCRIPTION OF THE DRAWINGS

These and/or other aspects and features of embodiments of the present

disclosure will become apparent and more readily appreciated from the following description of embodiments, taken in conjunction with the accompanying drawings in which:

FIG. 1 is a perspective view of a display device according to one or more embodiments;

FIG. 2 is a layout view of the display device according to one or more embodiments;

FIG. 3 is a block diagram of the display device according to one or more embodiments;

FIG. 4 is an equivalent circuit diagram of a subpixel according to one or more embodiments;

FIG. 5 is a layout view illustrating pixels of a display area according to one or more embodiments;

FIG. 6 is a cross-sectional view illustrating an example of a cross section of a display panel corresponding to the line I1-I1′ of FIG. 5;

FIG. 7 is a detailed cross-sectional view of an example of an area A of FIG. 6;

FIG. 8 is a cross-sectional view illustrating an example of a cross section of a display panel corresponding to the line I1-I1′ of FIG. 5;

FIG. 9 is a cross-sectional view illustrating an example of a cross section of a display panel corresponding to the line I1-I1′ of FIG. 5;

FIG. 10 is a cross-sectional view illustrating an example of a cross section of

a display panel corresponding to the line I1-I1′ of FIG. 5;

FIG. 11 is a detailed cross-sectional view of an example of an area B of FIG. 8;

FIG. 12 is a detailed cross-sectional view of an example of the area B of FIG. 8;

FIG. 13 is a detailed cross-sectional view of an example of the area B of FIG. 8;

FIG. 14 is a layout view of a pixel of a display area according to one or more embodiments;

FIG. 15 is a cross-sectional view illustrating an example of a cross section of a display panel corresponding to the line I2-I2′ of FIG. 14;

FIG. 16 is a cross-sectional view illustrating an example of a cross section of a display panel corresponding to the line I2-I2′ of FIG. 14;

FIG. 17 is a layout view of a pixel of a display area according to one or more embodiments;

FIG. 18 is a cross-sectional view illustrating an example of a cross section of a display panel corresponding to the line I3-I3′ of FIG. 17;

FIG. 19 is a layout view of a pixel of a display area according to one or more embodiments;

FIG. 20 is a cross-sectional view illustrating an example of a cross section of a display panel corresponding to the line I4-I4′ of FIG. 19;

FIG. 21 is a cross-sectional view illustrating an example of a cross section of a display panel corresponding to the line I4-I4′ of FIG. 19;

FIG. 22 is a layout view of a pixel of a display area according to one or more embodiments;

FIG. 23 is a cross-sectional view illustrating an example of a cross section of a display panel corresponding to the line I5-I5′ of FIG. 22;

FIG. 24 is a cross-sectional view illustrating an example of a cross section of

a display panel corresponding to the line I4-I4′ of FIG. 19;

FIG. 25 is a cross-sectional view illustrating an example of a cross section of a display panel corresponding to the line I4-I4′ of FIG. 19;

FIG. 26 is a layout view of a pixel of a display area according to one or more embodiments;

FIG. 27 is a cross-sectional view illustrating an example of a cross section of a display panel corresponding to the line I6-I6′ of FIG. 26;

FIG. 28 is an example view of a smart watch including a display device according to one or more embodiments;

FIGS. 29 and 30 are example views of a virtual reality (VR) device including a display device according to one or more embodiments;

FIG. 31 is an example view of a VR device including a display device according to one or more embodiments;

FIG. 32 is an example view illustrating a vehicle instrument cluster and center fascia including display devices according to one or more embodiments; and

FIG. 33 is an example view of a transparent display device including a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein.

Rather, these embodiments are provided so that the present disclosure will be thorough and complete, and will fully convey the scope of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, and/or combinations thereof.

As used herein, “directly disposed” may mean that there is no layer, film, region, plate, etc. added between a portion such as a layer, film, region, or plate and another portion. For example, “directly disposed” may mean that two layers or two members are disposed without using an additional member such as an adhesive member therebetween.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized and/or overly formal sense unless expressly so defined herein.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, a display panel according to one or more embodiments of the present disclosure and a manufacturing method of a display panel will be described with reference to the accompanying drawings.

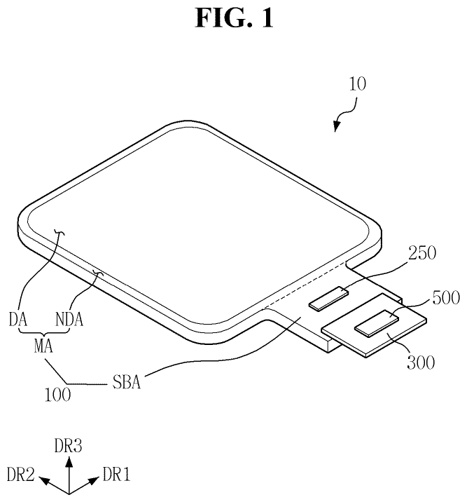

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display device such as an organic light emitting display device using an organic light emitting diode (OLED), a quantum dot light emitting display device including a quantum dot light emitting layer, an inorganic light emitting display device including an inorganic semiconductor, or a micro-or nano-light emitting display device using a micro-or nano-light emitting diode (LED). A case where the display device 10 is a micro-or nano-light emitting display device will be mainly described below, but the present disclosure is not limited thereto. For ease of description, a micro-or nano-LED will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, and/or an elliptical shape. The display panel 100 may be formed flat, but the present disclosure is not limited thereto.

For example, the display panel 100 may include a curved portion formed at left and right ends and having a constant or varying curvature. In addition, the display panel 100 may be formed to be flexible so that it can be curved, bent, folded, and/or rolled.

The display panel 100 may include a main area MA and a sub-area SBA.

The main area MA may include a display area DA that displays an image and a non-display area NDA disposed around the display area DA along an edge or a periphery of the display area DA. The display area DA may include a plurality of pixels that display an image. Each of the pixels may include a plurality of subpixels. For example, each of the pixels may include a first subpixel that emits first light, a second subpixel that emits second light, and a third subpixel that emits third light, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3, which is a thickness direction of the display panel 100 (e.g., a third direction DR3). The display driving circuit 250 may be disposed in the sub-area SBA.

The display driving circuit 250 may generate signals and voltages for driving the display panel 100. The display driving circuit 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and/or driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage from the outside. The power supply unit 500 may be formed as an integrated circuit and attached onto the circuit board 300 using a COF method.

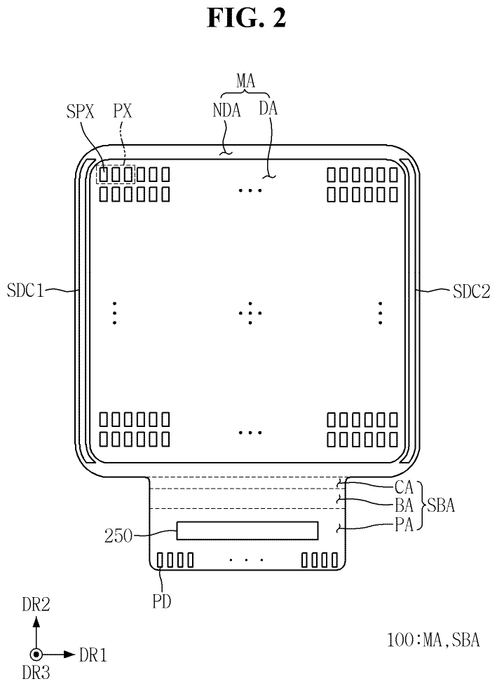

FIG. 2 is a layout view of the display device 10 according to one or more embodiments. FIG. 2 illustrates a state in which the sub-area SBA is unfolded.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in the center of the main area MA.

The display area DA may include a plurality of pixels PX for displaying an

image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may surround the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

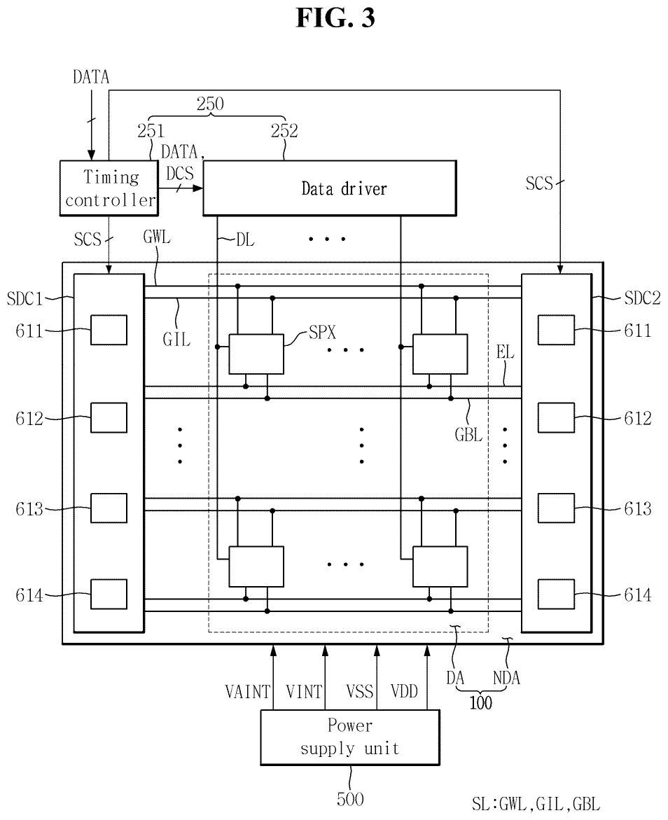

FIG. 3 is a block diagram of the display device 10 according to one or more embodiments.

Referring to FIG. 3, the display area DA includes a plurality of pixels PX, a plurality of scan lines SL, a plurality of emission control lines EL, and a plurality of data lines DL.

The pixels PX may be arranged in a matrix form along the first direction DR1 and the second direction DR2. For example, the pixels PX may be arranged along rows and columns of a matrix form along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of initialization scan lines GIL, and a plurality of bias scan lines GBL.

Each of the subpixels SPX may be connected to one of the write scan lines

GWL, one of the initialization scan lines GIL, one of the bias scan lines GBL, one of the emission control lines EL, and one of the data lines DL. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission control signal output unit 614.

Each of the write scan signal output unit 611, the initialization scan signal output unit 612, the bias scan signal output unit 613, and the emission control signal output unit 614 may receive a scan timing control signal SCS from a timing controller 251 of the display driving circuit 250.

The write scan signal output unit 611 may generate write scan signals

according to the scan timing control signal SCS of the timing controller 251 and sequentially output the write scan signals to the write scan lines GWL.

The initialization scan signal output unit 612 may generate initialization scan signals according to the scan timing control signal SCS and sequentially output the initialization scan signals to the initialization scan lines GIL.

The bias scan signal output unit 613 may generate bias scan signals

according to the scan timing control signal SCS and sequentially output the bias scan signals to the bias scan lines GBL. The emission control signal output unit 614 may generate emission control signals according to the scan timing control signal SCS and sequentially output the emission control signals to the emission control lines EL.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage supplied from the outside. For example, the power supply unit 500 may generate a first power supply voltage VDD, a second power supply voltage VSS, a third power supply voltage VINT, and a fourth power supply voltage VAINT and supply them to the display panel 100.

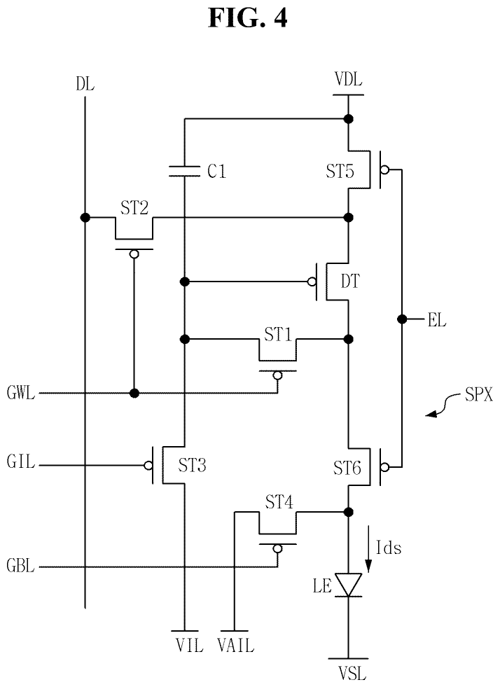

FIG. 4 is an equivalent circuit diagram of a subpixel SPX according to one or more embodiments.

Referring to FIG. 4, the subpixel SPX according to one or more embodiments may be connected to scan lines GWL, GIL and GBL, an emission control line EL, and a data line DL. For example, the subpixel SPX may be connected to a write scan line GWL, an initialization scan line GIL, a bias scan line GBL, the emission control line EL, and the data line DL.

The subpixel SPX according to one or more embodiments includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode of the driving transistor DT according to a data voltage applied to the gate electrode of the driving transistor DT.

The light emitting element LE may be a micro-LED.

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power line VSL to which the second power supply voltage VSS (see FIG. 3) is applied.

The capacitor C1 is formed between the gate electrode of the driving transistor DT and a first power line VDL to which the first power supply voltage VDD (see FIG. 3) is applied. The first power supply voltage VDD may be at a higher level than the second power supply voltage VSS. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as P-type metal-oxide-semiconductor field effect transistors (P-type MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, and a gate electrode of the fourth transistor ST4 may be connected to the bias scan line GBL. Because the first through sixth transistors ST1 through ST6 are formed as P-type MOSFETs, they may be turned on when a scan signal of a gate-low voltage and an emission control signal of a gate-low voltage are transmitted to the initialization scan line GIL, the write scan line GWL, the bias scan line GBL, and the emission control line EL. One electrode of the third transistor ST3 may be connected to a first initialization voltage line VIL to which the third power supply voltage VINT (see FIG. 3) is applied, and one electrode of the fourth transistor ST4 may be connected to a second initialization voltage line VAIL to which the fourth power supply voltage VAINT (see

FIG. 3) is applied. The third power supply voltage VINT (see FIG. 3) and the fourth power supply voltage VAINT (see FIG. 3) may be different voltages. In addition, the third power supply voltage VINT (see FIG. 3) and the fourth power supply voltage VAINT (see FIG. 3) may be at a lower level than the first power supply voltage VDD and may be at a higher level than the second power supply voltage VSS.

Alternatively, the driving transistor DT, the second transistor ST2, the fourth transistor ST4, the fifth transistor ST5 and the sixth transistor ST6 may be formed as P-type MOSFETs, and the first transistor ST1 and the third transistor ST3 may be formed as N-type MOSFETs. In this case, the active layer of each of the driving transistor DT, the second transistor ST2, the fourth transistor ST4, the fifth transistor ST5 and the sixth transistor ST6 formed as P-type MOSFETs may be made of polysilicon, and the active layer of each of the first transistor ST1 and the third transistor ST3 formed as N-type MOSFETs may be made of an oxide semiconductor. In addition, because the first transistor ST1 and the third transistor ST3 are formed as N-type MOSFETs, the first transistor ST1 may be turned on in response to a scan signal of a gate-high voltage, and the third transistor ST3 may be turned on in response to an initialization scan signal of a gate-high voltage. On the other hand, because the second transistor ST2, the fourth transistor ST4, the fifth transistor ST5 and the sixth transistor ST6 are formed as P-type MOSFETs, they may be turned on in response to a scan signal of a gate-low voltage and an emission control signal of a gate-low voltage.

Alternatively, the fourth transistor ST4 may be formed as an N-type MOSFET, and the other transistors DT, ST1, ST2, ST3, ST5 and ST6 may be formed as P-type MOSFETs. In this case, the active layer of the fourth transistor ST4 may be made of an oxide semiconductor, and the active layer of each of the other transistors DT, ST1, ST2, ST3, ST5 and ST6 may be made of polysilicon. In addition, the fourth transistor ST4 may be turned on in response to a scan signal of a gate-high voltage, and the other transistors DT, ST1, ST2, ST3, ST5 and ST6 may be turned on in response to a scan signal of a gate-low voltage and an emission control signal.

Alternatively, the first through sixth transistors ST1 through ST6 and the driving transistor DT may all be formed as N-type MOSFETs. In this case, the first through sixth transistors ST1 through ST6 and the driving transistor DT may each have the active layer made of an oxide semiconductor and may be turned on in response to a scan signal of a gate-high voltage and an emission control signal.

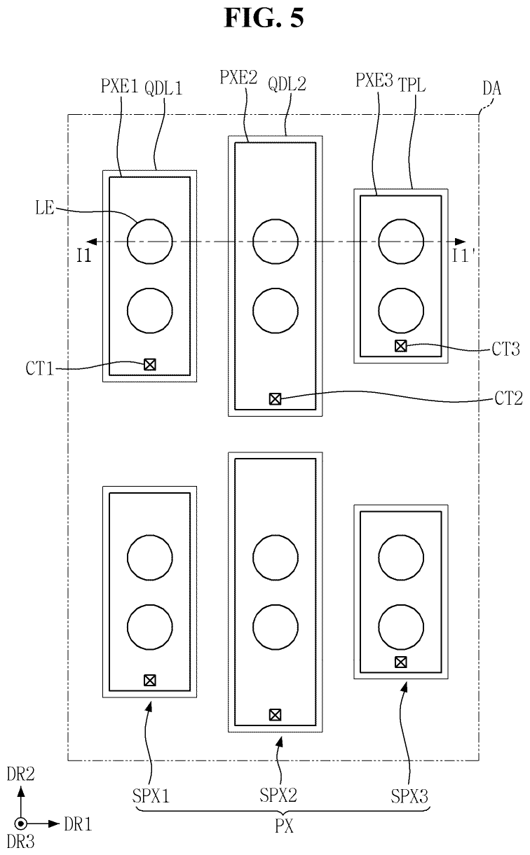

FIG. 5 is a layout view illustrating pixels PX of a display area DA according to one or more embodiments.

Referring to FIG. 5, each of the pixels PX in the display area DA may include three subpixels SPX1 through SPX3. However, the present disclosure is not limited thereto, and each of the pixels PX may also include four subpixels. When each of the pixels PX includes three subpixels SPX1 through SPX3, it may include a first subpixel SPX1, a second subpixel SPX2, and a third subpixel SPX3.

The pixels PX may be arranged in a matrix form. In each of the pixels PX,

the first subpixel SPX1, the second subpixel SPX2, and the third subpixel SPX3 may be arranged along the first direction DR1.

When each of the pixels PX includes three subpixels SPX1 through SPX3, the first subpixel SPX1 may output first light, the second subpixel SPX2 may output second light, and the third subpixel SPX3 may output third light. Here, the first light may be light in a blue wavelength band, the second light may be light in a green wavelength band, and the third light may be light in a red wavelength band. For example, the blue wavelength band may indicate that a main peak wavelength of light is included in a wavelength band of about 370 to 460 nm, the green wavelength band may indicate that a main peak wavelength of light is included in a wavelength band of about 480 to 560 nm, and the red wavelength band may indicate that a main peak wavelength of light is included in a wavelength band of about 600 to 750 nm.

Alternatively, when each of the pixels PX includes four subpixels, a first subpixel may output first light, a second subpixel and a fourth subpixel may output second light, and a third subpixel may output third light. Alternatively, the first subpixel may output first light, the second subpixel may output second light, the third subpixel may output third light, and the fourth subpixel may output fourth light. Here, the fourth light may be white light.

The first subpixel SPX1 includes a first pixel electrode PXE1, a plurality of light emitting elements LE, and a first light conversion layer QDL1. The second subpixel SPX2 includes a second pixel electrode PXE2, a plurality of light emitting elements LE, and a second light conversion layer QDL2. The third subpixel SPX3 includes a third pixel electrode PXE3, a plurality of light emitting elements LE, and a light transmission layer (or a third light conversion layer) TPL.

Each of the first pixel electrode PXE1, the second pixel electrode PXE2, and the third pixel electrode PXE3 may be shaped like a rectangular plane having short sides in the first direction DR1 and long sides in the second direction DR2. The area of the first subpixel SPX1, the area of the second subpixel SPX2, and the area of the third subpixel SPX3 may be set according to the light conversion efficiency of the first light conversion layer QDL1 and the light conversion efficiency of the second light conversion layer QDL2. For example, the lower the light conversion efficiency, the larger the area of a subpixel.

For example, as illustrated in FIG. 5, when the light conversion efficiency of the second light conversion layer QDL2 is lower than the light conversion efficiency of the first light conversion layer QDL1, the area of the second pixel electrode PXE2 may be greater than the area of the first pixel electrode PXE1. In addition, because the first light conversion layer QDL1 must convert light whereas the light transmission layer TPL transmits light of the light emitting elements LE as it is, the area of the first pixel electrode PXE1 may be greater than the area of the third pixel electrode PXE3.

Each of the pixel electrodes PXE1 through PXE3 may be electrically connected to at least one transistor through a pixel connection hole CT1/CT2/CT3. For example, each of the pixel electrodes PXE1 through PXE3 may be electrically connected to the first electrode of the fourth transistor ST4 (see FIG. 4) and the second electrode of the sixth transistor ST6 (see FIG. 4) of a corresponding subpixel.

A plurality of light emitting elements LE may be disposed on each of the pixel electrodes PXE1 through PXE3. The same number of light emitting elements LE may be disposed on each of the pixel electrodes PXE1 through PXE3. For example, two light emitting elements LE may be disposed on each of the pixel electrodes PXE1 through PXE3. The light emitting elements LE may emit third light, for example, light in the blue wavelength band, but the present disclosure is not limited thereto. If the light emitting elements LE of the first subpixel SPX1 emit first light, the light emitting elements LE of the second subpixel SPX2 emit second light, and the light emitting elements LE of the third subpixel SPX3 emit third light, the light conversion layers QDL1 and QDL2 and the light transmission layer TPL may be omitted.

The first light conversion layer QDL1 may completely overlap the first pixel electrode PXE1 and the light emitting elements LE of the first subpixel SPX1. The area of the first light conversion layer QDL1 may be greater than the area of the first pixel electrode PXE1. The first light conversion layer QDL1 may convert or shift a peak wavelength of incident light into light of another specific peak wavelength and output the light of the specific peak wavelength. For example, the first light conversion layer QDL1 may convert or shift third light emitted from the light emitting elements LE of the first subpixel SPX1 into first light.

The second light conversion layer QDL2 may completely overlap the second pixel electrode PXE2 and the light emitting elements LE of the second subpixel SPX2. The area of the second light conversion layer QDL2 may be greater than the area of the second pixel electrode PXE2. The second light conversion layer QDL2 may convert or shift a peak wavelength of incident light into light of another specific peak wavelength and output the light of the specific peak wavelength. For example, the second light conversion layer QDL2 may convert or shift third light emitted from the light emitting elements LE of the second subpixel SPX2 into second light.

The light transmission layer TPL may completely overlap the third pixel

electrode PXE3 and the light emitting elements LE of the third subpixel SPX3. The light transmission layer TPL may transmit incident light as it is. For example, the light transmission layer TPL may transmit third light emitted from the light emitting elements LE of the third subpixel SPX3 as it is.

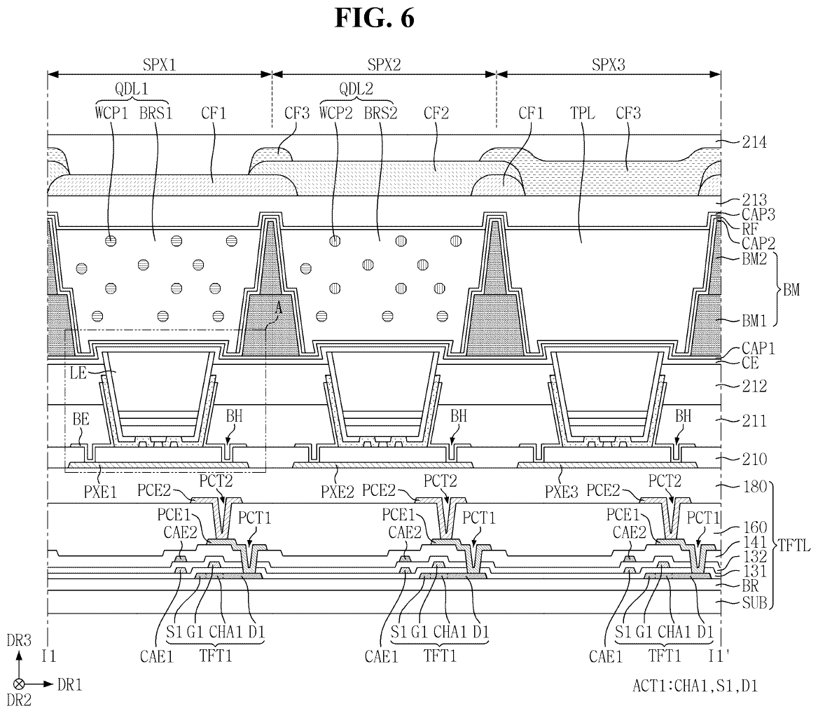

FIG. 6 is a cross-sectional view illustrating an example of a cross section of

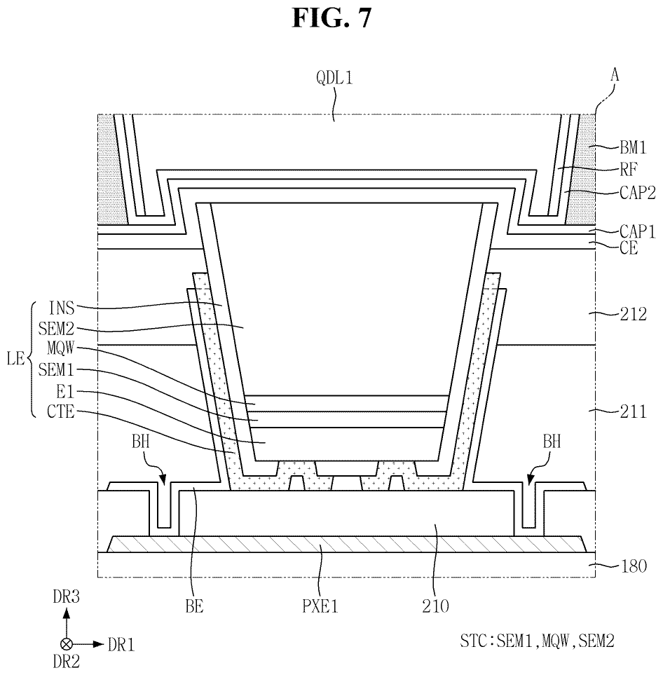

the display panel 100 corresponding to the line I1-I1′ of FIG. 5. FIG. 7 is a detailed cross-sectional view of an example of an area A of FIG. 6.

Referring to FIGS. 6 and 7, a substrate SUB may be made of an insulating material such as glass and/or polymer resin. When the substrate SUB is made of polymer resin, it may be a flexible substrate that can be stretched. The polymer resin may be acryl resin, epoxy resin, phenolic resin, polyamide resin, and/or polyimide resin.

A barrier layer BR may be disposed on the substrate SUB. The barrier layer BR is a layer for protecting transistors of a thin-film transistor layer TFTL and light emitting elements LE disposed on the thin-film transistor layer TFTL from moisture introduced through the substrate SUB which is vulnerable to moisture penetration. The barrier layer BR may be composed of a plurality of inorganic layers stacked alternately.

Thin-film transistors TFT1 may be disposed on the barrier layer BR. Each of

the thin-film transistors TFT1 may be one of the fourth transistor ST4 and the sixth transistor ST6 illustrated in FIG. 4. Each of the thin-film transistors TFT1 may include a first active layer ACT1 and a first gate electrode G1.

The first active layer ACT1 of each of the thin-film transistors TFT1 may be disposed on the barrier layer BR. The first active layer ACT1 of each of the thin-film transistors TFT1 may include polycrystalline silicon, monocrystalline silicon, low-temperature polycrystalline silicon, and/or amorphous silicon. Alternatively, the first active layer ACT1 of each of the thin-film transistors TFT1 may be made of an oxide semiconductor including IGZO (indium (In), gallium (Ga), zinc (Zn) and oxygen (O)), IGZTO (indium (In), gallium (Ga), zinc (Zn), tin (Sn) and oxygen (O)), and/or IGTO (indium (In), gallium (Ga), tin (Sn) and oxygen (O)).

The first active layer ACT1 may include a first channel region CHA1, a first source region S1, and a first drain region D1. The first channel region CHA1 may be a region overlapped by the first gate electrode G1 in the third direction DR3 which is the thickness direction of the substrate SUB. The first source region S1 may be disposed on a side of the first channel region CHA1, and the first drain region D1 may be disposed on the other side of the first channel region CHA1. The first source region S1 and the first drain region D1 may be regions not overlapped by the first gate electrode G1 in the third direction DR3. The first source region S1 and the first drain region D1 may be regions formed to have conductivity by doping a semiconductor material with ions.

A first gate insulating layer 131 may be disposed on the first channel regions CHA1, the first source regions S1, and the first drain regions D1 of the thin-film transistors TFT1 and the barrier layer BR.

A first gate metal layer may be disposed on the first gate insulating layer 131. The first gate metal layer may include the first gate electrodes G1 of the thin-film transistors TFT1 and first capacitor electrodes CAE1. The first gate electrodes G1 may overlap the first active layers ACT1 in the third direction DR3. In FIG. 6, the first gate electrodes G1 and the first capacitor electrodes CAE1 are spaced (e.g., spaced apart) from each other. However, when each of the thin-film transistors TFT1 is the driving transistor DT of FIG. 4, the first gate electrodes G1 and the first capacitor electrodes

CAE1 may be electrically or physically connected to each other. Alternatively, when each of the thin-film transistors TFT1 is one of the first through sixth transistors ST1 through ST6 of FIG. 4, the first gate electrodes G1 and the first capacitor electrodes CAE1 may not be electrically or physically connected to each other.

A second gate insulating layer 132 may be disposed on the first gate electrodes G1 of the thin-film transistors TFT1, the first capacitor electrodes CAE1, and the first gate insulating layer 131.

A second gate metal layer may be disposed on the second gate insulating layer 132. The second gate metal layer may include second capacitor electrodes CAE2. The second capacitor electrodes CAE2 may overlap the first capacitor electrodes CAE1 in the third direction DR3. Because the second gate insulating layer 132 has a suitable dielectric constant (e.g., a predetermined dielectric constant), capacitors C1 (see FIG. 4) may be formed by the first capacitor electrodes CAE1, the second capacitor electrodes CAE2, and the second gate insulating layer 132 disposed between them.

A first interlayer insulating layer 141 may be disposed on the second capacitor electrodes CAE2 and the second gate insulating layer 132.

A first data metal layer may be disposed on the interlayer insulating layer 141. The first data metal layer may include first source connection electrodes PCE1.

The first source connection electrodes PCE1 may be connected to the first drain regions D1 of the first active layers ACT1 through first source contact holes PCT1 penetrating the first gate insulating layer 131, the second gate insulating layer 132, and the interlayer insulating layer 141.

A first planarization layer 160 may be disposed on the first source connection electrodes PCE1 and the first interlayer insulating layer 141 to flatten steps caused by the thin-film transistors TFT1.

A second data metal layer may be disposed on the first planarization layer 160. The second data metal layer may include second source connection electrodes PCE2. The second source connection electrodes PCE2 may be connected to the first source connection electrodes PCE1 through second source contact holes PCT2 penetrating the first planarization layer 160.

A second planarization layer 180 may be disposed on the second source connection electrodes PCE2 and the first planarization layer 160.

The barrier layer BR, the first gate insulating layer 131, the second gate

insulating layer 132, and the interlayer insulating layer 141 may be made of an inorganic layer, for example, silicon nitride (SiNₓ), silicon oxynitride (SiON), silicon oxide (SiOₓ), titanium oxide (TiOₓ), and/or aluminum oxide (AlOₓ).

The first gate metal layer, the second gate metal layer, the first data metal layer, and the second data metal layer may each be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

The first planarization layer 160 and the second planarization layer 180 may be made of an organic layer such as acryl resin, epoxy resin, phenolic resin, polyamide resin, and/or polyimide resin.

A light emitting element layer may be disposed on the second planarization layer 180. The light emitting element layer may include pixel electrodes PXE1 through PXE3, light emitting elements LE, a common electrode CE, and organic layers 210, 211 and 212.

A pixel electrode layer may be disposed on the second planarization layer 180. The pixel electrode layer may include a first pixel electrode PXE1, a second pixel electrode PXE2, and a third pixel electrode PXE3. In one or more embodiments, each of the pixel electrodes PXE1 through PXE3 may be connected to a second source connection electrode PCE2 through a pixel connection hole CT1/CT2/CT3 (see FIG. 5) penetrating the second planarization layer 180. Each of the pixel electrodes PXE1 through PXE3 may be connected to the first source region S1 or the first drain region D1 of a thin-film transistor TFT1 through a first source connection electrode PCE1 and a second source connection electrode PCE2. Therefore, a voltage controlled by a thin-film transistor TFT1 may be applied to each of the pixel electrodes PXE1 through PXE3.

The pixel electrode layer may be a single layer or a multilayer made of one or more of molybdenum (Mo), aluminum (AI), chromium (Cr), gold (Au), titanium (Ti), nickel (Ni), neodymium (Nd), copper (Cu), and/or alloys thereof. For example, the pixel electrode layer may be made of copper (Cu) with low sheet resistance in order to lower the resistance of each of the pixel electrodes PXE1 through PXE3. A first organic layer 210 may be disposed on each of the pixel electrodes

PXE1 through PXE3. The first organic layer 210 temporarily fixes or attaches a plurality of light emitting elements LE to prevent the light emitting elements LE from tilting or falling during a process of transferring the light emitting elements LE to the display panel 100. That is, the first organic layer 210 may be a layer for temporarily attaching a plurality of light emitting elements LE onto each of the pixel electrodes PXE1 through PXE3. To facilitate the temporary adhesion, the first organic layer 210 may be thicker than each of the pixel electrodes PXE1 through PXE3 and thicker than contact electrodes CTE.

The first organic layer 210 may be a photosensitive organic layer such as photoresist. Alternatively, the first organic layer 210 may be made of acryl resin, epoxy resin, phenolic resin, polyamide resin, and/or polyimide resin.

The light emitting elements LE may be disposed on the first organic layer 210. In FIG. 6, each of the light emitting elements LE is a vertical type micro-LED extending in the third direction DR3. The vertical type micro-LED refers to an LED having a structure in which a first semiconductor layer SEM1, an active layer MQW, and a second semiconductor layer SEM2 are sequentially disposed along the third direction DR3 which is a vertical direction.

Each of the light emitting elements LE may have a reverse-tapered cross-sectional shape. For example, each of the light emitting elements LE may have a trapezoidal cross-sectional shape whose upper surface is wider than a lower surface.

Each of the light emitting elements LE may be made of an inorganic material such as gallium nitride (GaN). Each of the light emitting elements LE may have a length of several to hundreds of um in each of the first direction DR1, the second direction DR2, and the third direction DR3. For example, each of the light emitting elements LE may have a length of about 100 μm or less in each of the first direction DR1, the second direction DR2, and the third direction DR3.

Each of the light emitting elements LE may be grown on a semiconductor substrate such as a silicon substrate and/or a sapphire substrate. The light emitting elements LE may be directly transferred from the semiconductor substrate onto the pixel electrodes PXE1 through PXE3 of the display panel 100. Alternatively, the light emitting elements LE may be transferred onto the pixel electrodes PXE1 through PXE3 of the display panel 100 through an electrostatic method using an electrostatic head and/or a stamp method using an elastic polymer material, such as PDMS and/or silicon, as a transfer substrate.

Each of the light emitting elements LE may include a conductive layer E1, a semiconductor stack STC, contact electrodes CTE, and a protective layer INS. The semiconductor stack STC may include the first semiconductor layer SEM1, the active layer MQW, and the second semiconductor layer SEM2 sequentially disposed along the third direction DR3.

The conductive layer E1 may be disposed on a lower surface of the first semiconductor layer SEM1. Although the conductive layer E1 covers the entire lower surface of the first semiconductor layer SEM1 in FIG. 7, the present disclosure is not limited thereto. For example, the conductive layer E1 may also be disposed on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. A length of the lower surface of the first semiconductor layer SEM1 in the first direction DR1 or in the second direction DR2 may be smaller than a length of contact electrodes CTE in the first direction DR1 or in the second direction DR2. The first semiconductor layer SEM1 may be made of a semiconductor material layer, for example, gallium nitride (GaN) doped with a first conductivity type dopant such as magnesium (Mg), zinc (Zn), calcium (Ca), strontium (Sr), and/or barium (Ba).

The active layer MQW may be disposed on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light through combination of electron-hole pairs according to electrical signals received through the first semiconductor layer SEM1 and the second semiconductor layer SEM2.

The active layer MQW may include a material having a single or multiple

quantum well structure. When the active layer MQW includes a material having a multiple quantum well structure, it may be a structure in which a plurality of well layers and a plurality of barrier layers are alternately stacked. Here, the well layers may be made of InGaN, and the barrier layers may be made of GaN or AlGaN, but the present disclosure is not limited thereto. Alternatively, the active layer MQW may be a structure in which a semiconductor material having a large band gap energy and a semiconductor material having a small band gap energy are alternately stacked or may include different group III to V semiconductor materials depending on the wavelength band of light that it emits.

When the active layer MQW includes indium gallium nitride (InGaN), the

color of light that it emits may vary according to indium content. For example, as the indium content increases, the wavelength band of light emitted from the active layer MQW may move to the red wavelength band, and as the indium content decreases, the wavelength band of light emitted from the active layer MQW may move to the blue wavelength band. For example, the indium content of the active layer MQW of a light emitting element LE that emits third light (light in the blue wavelength band) may be about 10 to 20 wt %.

The second semiconductor layer SEM2 may be disposed on the active layer MQW. The second semiconductor layer SEM2 may be made of a semiconductor material layer, for example, gallium nitride (GaN) doped with a second conductivity type dopant such as silicon (Si), germanium (Ge), and/or tin (Sn).

An electron blocking layer may be disposed between the first semiconductor layer SEM1 and the active layer MQW. The electron blocking layer may be a layer for suppressing or preventing too many electrons from flowing into the active layer MQW.

For example, the electron blocking layer may be AlGaN and/or p-AlGaN doped with p-type Mg. The electron blocking layer can be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be made of InGaN and/or GaN. The superlattice layer may be omitted.

The protective layer INS may be disposed on side surfaces (e.g., outer peripheral or circumferential surfaces) of the conductive layer E1, the first semiconductor layer SEM1, side surfaces of the active layer MQW, and side surfaces of the second semiconductor layer SEM2. The protective layer INS may be a layer for protecting side surfaces of a light emitting element LE. The protective layer INS may be made of an inorganic layer, for example, silicon nitride (SiNₓ), silicon oxynitride (SiON), silicon oxide (SiOₓ), titanium oxide (TiOₓ), or aluminum oxide (AlOₓ).

The contact electrodes CTE may be disposed on the side surfaces (e.g., outer peripheral or circumferential surfaces) the protective layer INS. The contact electrodes CTE may be disposed between the first organic layer 210 and the protective layer INS. The contact electrodes CTE may contact the first organic layer 210.

Although the contact electrodes CTE of each of the light emitting elements

LE are disposed on the first organic layer 210 in FIGS. 6 and 7, the present disclosure is not limited thereto. For example, the first organic layer 210 may be disposed on a lower surface and a portion of a side surface of each contact electrode CTE of each of the light emitting elements LE. Alternatively, the first organic layer 210 may be disposed on side surfaces of the conductive layer E1 of each of the light emitting elements LE. Alternatively, the first organic layer 210 may be disposed on the side surfaces of the first semiconductor layer SEM1, the side surfaces of the active layer MQW, and the side surfaces of the second semiconductor layer SEM2 of each of the light emitting elements LE. In this case, the first organic layer 210 may be disposed on a portion of each side surface of the second semiconductor layer SEM2.

The contact electrodes CTE may be connected to the conductive layer E1 exposed without being covered by the protective layer INS. Accordingly, even if one of the contact electrodes CTE is not connected to the conductive layer E1 due to a process error, the other contact electrode CTE may be connected to the conductive layer E1, thereby preventing a light emitting element LE from not lighting up.

When the contact electrodes CTE are made of a metal with high reflectivity, light travelling in a lateral direction of the light emitting element LE from among light emitted from the active layer MQW of the light emitting element LE may be reflected by the contact electrodes CTE to exit from an upper surface of the light emitting element LE. Accordingly, a loss of light of the light emitting element LE can be reduced, and thus the light efficiency of the light emitting element LE can be increased. Therefore, in order to increase the light efficiency of the light emitting element LE, the contact electrodes CTE may cover most of side surfaces (e.g., outer peripheral or circumferential surfaces) of the semiconductor stack STC.

The contact electrodes CTE may include molybdenum (Mo), aluminum (Al), chromium (Cr), gold (Au), titanium (Ti), nickel (Ni), neodymium (Nd), and/or copper (Cu). Specifically, to increase reflectivity, the contact electrodes CTE may have a two-layer structure of chromium (Cr) and gold (Au), a three-layer structure of titanium (Ti), aluminum (Al) and titanium (Ti), or a three-layer structure of indium tin oxide (ITO), silver (Ag) and indium tin oxide (ITO).

Connection electrodes BE connect the contact electrodes CTE of each light emitting element LE to one of the pixel electrodes PXE1 through PXE3. The connection electrodes BE may be connected to one of the pixel electrodes PXE1 through PXE3 exposed through connection holes BH penetrating the first organic layer 210. In addition, the connection electrodes BE may be disposed on an upper surface of the first organic layer 210 and the side surfaces (e.g., outer peripheral or circumferential surfaces) of the contact electrodes CTE. In addition, the connection electrodes BE may be disposed on a portion of the side surfaces of each light emitting element LE. For example, in one or more embodiments, the connection electrodes BE may be disposed on a portion of the protective layer INS of each light emitting element

LE.

The connection electrodes BE may include molybdenum (Mo), aluminum (Al), chromium (Cr), gold (Au), titanium (Ti), nickel (Ni), neodymium (Nd), and/or copper (Cu). Alternatively, the connection electrodes BE may be made of a transparent conductive material (TCO) that can transmit light, such as indium tin oxide (ITO) and/or indium zinc oxide (IZO).

When the connection electrodes BE are made of a metal material with high reflectivity such as aluminum (Al), light travelling in the lateral direction of a light emitting element LE from among light emitted from the active layer MQW of the light emitting element LE may be reflected by the connection electrodes BE toward the top of the light emitting element LE. Accordingly, a loss of light of the light emitting element LE can be reduced, and thus the light efficiency of the light emitting element LE can be increased.

A third organic layer 211 may partially cover the side surfaces of the light emitting elements LE. In addition, the third organic layer 211 may cover the connection electrodes BE, but at least a portion of each of the connection electrodes BE may be exposed without being covered by the third organic layer 211.

A fourth organic layer 212 may be disposed on the third organic layer 211. The fourth organic layer 212 may partially cover the side surfaces of each of the light emitting elements LE. In one or more embodiments, the fourth organic layer 212 may be disposed on at least a portion of each of the connection electrodes BE exposed without being covered by the third organic layer 211. The upper surface of each of the light emitting elements LE may be exposed without being covered by the fourth organic layer 212.

The third organic layer 211 and the fourth organic layer 212 may be made of an organic layer such as acryl resin, epoxy resin, phenolic resin, polyamide resin, and/or polyimide resin.

The third organic layer 211 and the fourth organic layer 212 are layers for flattening steps caused by the light emitting elements LE. If the third organic layer 211 is high enough to cover most of the side surfaces of each of the light emitting elements LE, the fourth organic layer 212 may be omitted.

The common electrode CE may be disposed on the upper surface of each of the light emitting elements LE and an upper surface of the fourth organic layer 212.

The common electrode CE may be a common layer commonly formed in the first subpixel SPX1, the second subpixel SPX2, and the third subpixel SPX3. The common electrode CE may be made of a transparent conductive material (TCO) that can transmit light, such as indium tin oxide (ITO) and/or indium zinc oxide (IZO).

The pixel electrodes PXE1 through PXE3 may be referred to as anodes or first electrodes, and the common electrode CE may be referred to as a cathode or a second electrode.

A first capping layer CAP1 may be disposed on the common electrode CE and may be a common layer commonly formed in the first subpixel SPX1, the second subpixel SPX2, and the third subpixel SPX3.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be disposed or formed in respective areas defined or partitioned by the light blocking layer BM. Therefore, the first light conversion layer QDL1 may be disposed on the first capping layer CAP1 in the first subpixel SPX1, the second light conversion layer QDL2 may be disposed on the first capping layer CAP1 in the second subpixel SPX2, and the light transmission layer TPL may be disposed on the first capping layer CAP1 in the third subpixel SPX3. The light blocking layer BM may overlap the third organic layer 211 and the fourth organic layer 212 in the third direction DR3 and may not overlap the light emitting elements LE.

The first light conversion layer QDL1 may convert a portion of third light (e.g., light in the blue wavelength band) incident from a light emitting element LE into first light (e.g., light in the red wavelength band). The first light conversion layer QDL1 may include a first base resin BRS1 and first wavelength conversion particles WCP1. The first base resin BRS1 may include a light-transmitting organic material. The first wavelength conversion particles WCP1 may convert a portion of the third light (e.g., light in the blue wavelength band) incident from the light emitting element LE into the first light (e.g., light in the red wavelength band).

The second light conversion layer QDL2 may convert a portion of third light (e.g., light in the blue wavelength band) incident from a light emitting element LE into second light (e.g., light in the green wavelength band). The second light conversion layer QDL2 may include a second base resin BRS2 and second wavelength conversion particles WCP2. The second base resin BRS2 may include a light-transmitting organic material. The second wavelength conversion particles WCP2 may convert a portion of the third light (e.g., light in the blue wavelength band) incident from the light emitting element LE into the second light (e.g., light in the green wavelength band).

The light transmission layer TPL may include a light-transmitting organic material.

For example, the first base resin BRS1, the second base resin BRS2, and the light transmission layer TPL may include epoxy resin, acrylic resin, cardo resin, and/or imide resin. The first and second wavelength conversion particles WCP1 and WCP2 may be quantum dots, quantum rods, fluorescent materials, and/or phosphorescent materials.

The light blocking layer BM may include a first light blocking layer BM1 and a second light blocking layer BM2 stacked sequentially. A length of the first light blocking layer BM1 in the first direction DR1 or a length of the first light blocking layer BM1 in the second direction DR2 may be greater than a length of the second light blocking layer BM2 in the first direction DR1 or a length of the second light blocking layer BM2 in the second direction DR2. The first light blocking layer BM1 and the second light blocking layer BM2 may be made of an organic layer such as acryl resin, epoxy resin, phenolic resin, polyamide resin, and/or polyimide resin. The first light blocking layer BM1 and the second light blocking layer BM2 may include a light blocking material to prevent light of a light emitting element LE of any one subpixel from travelling to a neighboring subpixel. For example, the first light blocking layer BM1 and the second light blocking layer BM2 may include an inorganic black pigment such as carbon black and/or an organic black pigment.

A second capping layer CAP2 may be disposed on the first capping layer CAP1 and the light blocking layer BM. The second capping layer CAP2 may be disposed on side and upper surfaces of the light blocking layer BM. For example, the second capping layer CAP2 may be disposed on side surfaces of the first light blocking layer BM1 and side and upper surfaces of the second light blocking layer BM2. A reflective layer RF may be disposed between the light blocking layer BM

and the first light conversion layer QDL1, between the light blocking layer BM and the second light conversion layer QDL2, and between the light blocking layer BM and the light transmission layer TPL. The reflective layer RF may be disposed on the second capping layer CAP2 disposed on the side surfaces of the first light blocking layer BM1 and the side surfaces of the second light blocking layer BM2. The reflective layer RF may reflect light travelling in the lateral direction from the first light conversion layer QDL1, the second light conversion layer QDL2, and the light transmission layer TPL.

The reflective layer RF may include a metal material with high reflectivity, such as aluminum (Al). A thickness of the reflective layer RF may be about 0.1 μm.

Alternatively, to serve as distributed Bragg reflectors, the reflective layer RF may include M (M is an integer of 2 or more) pairs of first and second layers having different refractive indices. In this case, M first layers and M second layers may be arranged alternately. The first and second layers may be made of an inorganic layer, for example, silicon nitride (SiNₓ), silicon oxynitride (SiON), silicon oxide (SiOₓ), titanium oxide (TiOₓ), and/or aluminum oxide (AlOₓ).

A third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be made of an inorganic layer, for example, silicon nitride (SiNₓ), silicon oxynitride (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capping layer CAP1, the second capping layer CAP2, and the third capping layer CAP3.

A fifth organic layer 213 may be disposed on the third capping layer CAP3. A plurality of color filters CF1 through CF3 may be disposed on the fifth organic layer 213. The color filters CF1 through CF3 may include first color filters CF1, second color filters CF2, and third color filters CF3.

The first color filter CF1 disposed in the first subpixel SPX1 may transmit first light (e.g., light in the red wavelength band) and absorb or block third light (e.g., light in the blue wavelength band). Therefore, the first color filter CF1 may transmit the first light (e.g., light in the red wavelength band) into which a portion of the third light (e.g., light in the blue wavelength band) emitted from a light emitting element LE has been converted by the first light conversion layer QDL1 and may absorb or block the third light (e.g., light in the blue wavelength band) which has not been converted by the first light conversion layer QDL1. Accordingly, the first subpixel SPX1 may output the first light (e.g., light in the red wavelength band).

A second color filter CF2 disposed in the second subpixel SPX2 may transmit second light (e.g., light in the green wavelength band) and absorb or block third light (e.g., light in the blue wavelength band). Therefore, the second color filter CF2 may transmit the second light (e.g., light in the green wavelength band) into which a portion of the third light (e.g., light in the blue wavelength band) emitted from a light emitting element LE has been converted by the second light conversion layer QDL2 and may absorb or block the third light (e.g., light in the blue wavelength band) which has not been converted by the second light conversion layer QDL2. Accordingly, the second subpixel SPX2 may output the second light (e.g., light in the green wavelength band).

A third color filter CF3 disposed in the third subpixel SPX3 may transmit third light (e.g., light in the blue wavelength band). Therefore, the third color filter CF3 may transmit the third light (e.g., light in the blue wavelength band) that passes through the light transmission layer TPL after being emitted from a light emitting element LE. Accordingly, the third subpixel SPX3 may emit the third light (e.g., light in the blue wavelength band).

The first color filter CF1, the second color filter CF2, and the third color filter CF3 overlapping each other in the third direction DR3 may overlap the light blocking layer BM in the third direction DR3.

A sixth organic layer 214 for planarization may be disposed on the color filters CF1 through CF3.

The fifth organic layer 213 and the sixth organic layer 214 may be made of

acryl resin, epoxy resin, phenolic resin, polyamide resin, and/or polyimide resin.

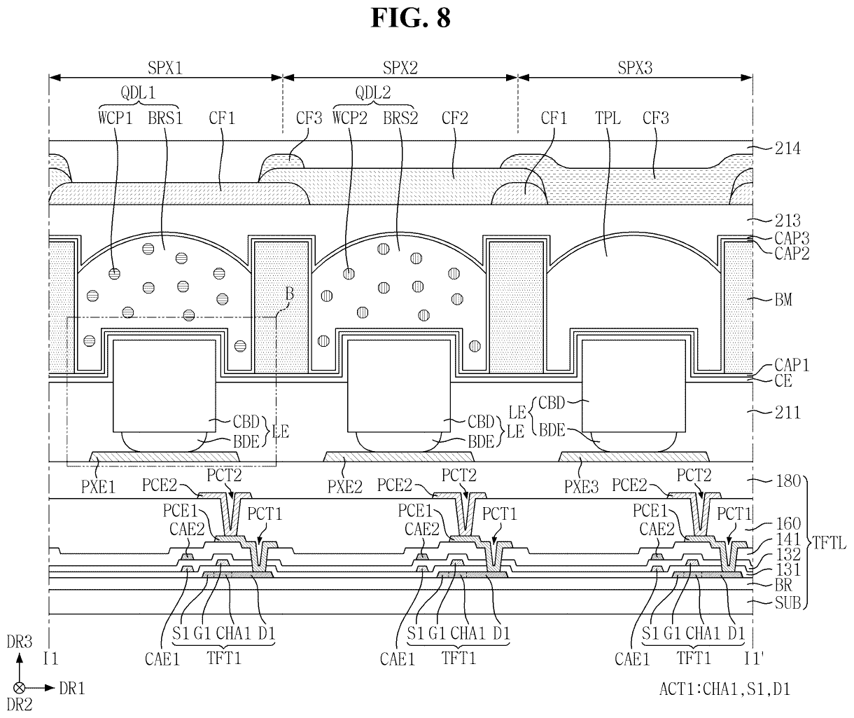

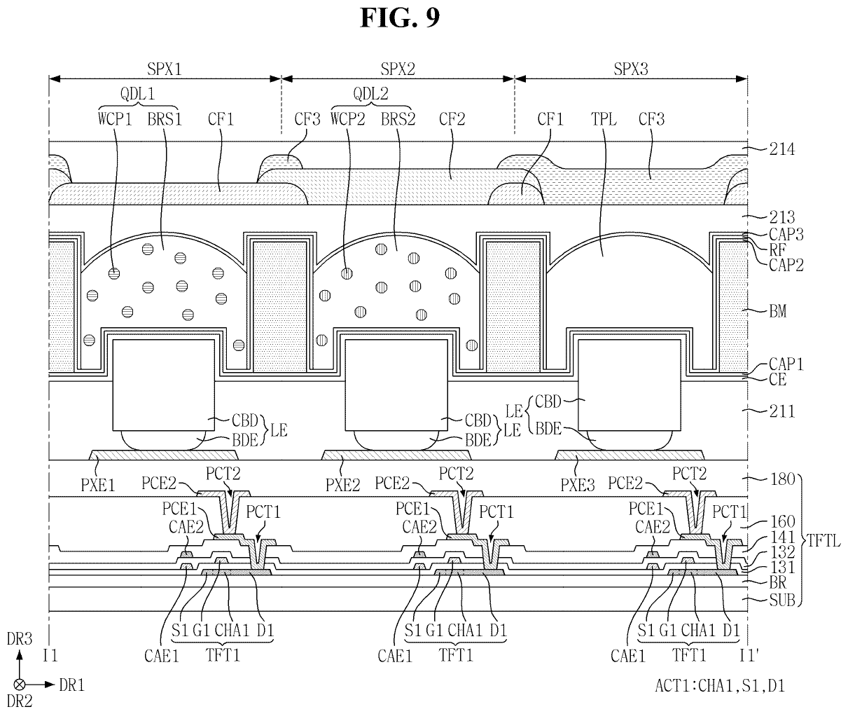

FIG. 8 is a cross-sectional view illustrating an example of a cross section of a display panel 100 corresponding to the line I1-I1′ of FIG. 5. FIG. 9 is a cross-sectional view illustrating an example of a cross section of a display panel 100 corresponding to the line I1-I1′ of FIG. 5.

FIGS. 8 and 9 show embodiments different from the embodiment of FIG. 6 in relation to a light emitting element layer including light emitting elements LE. In addition, FIGS. 8 and 9 show different embodiments in relation to a reflective layer RF. In the description of the embodiments of FIGS. 8 and 9, descriptions overlapping those of the embodiment of FIG. 6 will be omitted.

Referring to FIGS. 8 and 9, each of the light emitting elements LE may

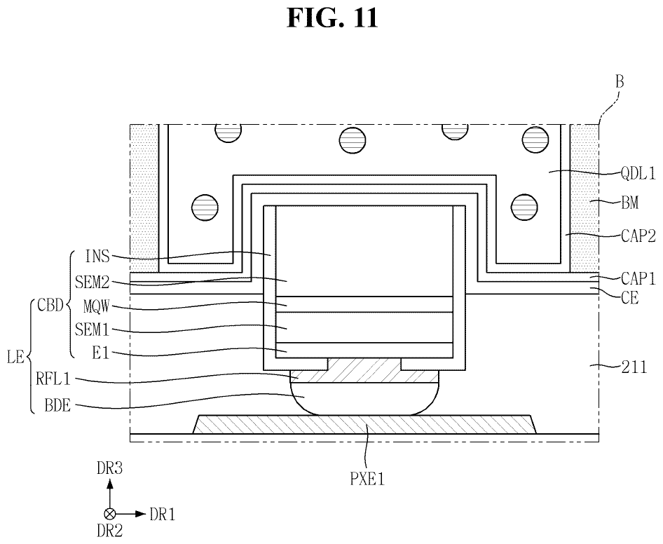

include a body portion CBD and a bonding electrode BDE disposed on a lower surface of the body portion CBD. The body portion CBD may be an LED chip body including an active layer MQW (see FIG. 11).

Each of the light emitting elements LE may be placed on a pixel electrode (or a bonding pad connected to the pixel electrode) of a corresponding subpixel SPX by the bonding electrode BDE. For example, the light emitting elements LE can be stably placed on pixel electrodes PXE1 through PXE3 using a bonding method such as eutectic bonding. In one or more embodiments, each of the pixel electrodes PXE1 through PXE3 may be, but is not limited to, a multilayer including a metal layer.

The body portion CBD of each of the light emitting elements LE may be electrically connected to a pixel electrode of a subpixel SPX through the bonding electrode BDE. The display panel 100 according to the embodiment of FIG. 8 may not include the organic layer 210 (and/or the organic layer 212) and the connection electrodes BE of FIG. 6.

In one or more embodiments, a portion of each of the light emitting elements LE may be disposed at a higher position than a third organic layer 211 and may be surrounded by a first light conversion layer QDL1, a second light conversion layer QDL2 or a light transmission layer TPL. For example, the display panel 100 according to the embodiment of FIG. 8 or FIG. 9 may not include the fourth organic layer 212 of FIG. 6, and the light emitting elements LE may protrude above the third organic layer 211.

The first light conversion layer QDL1, the second light conversion layer QDL2, and the light transmission layer TPL may be disposed in emission areas of the subpixels SPX separated by a light blocking layer BM. For example, the first light conversion layer QDL1, the second light conversion layer QDL2, and the light transmission layer TPL may be disposed in an emission area of the first subpixel SPX1, an emission area of the second subpixel SPX2, and an emission area of the third subpixel SPX3, respectively. The first light conversion layer QDL1, the second light conversion layer QDL2, and the light transmission layer TPL may be covered with a third capping layer CAP3.

In one or more embodiments, surfaces of the first light conversion layer QDL1, the second light conversion layer QDL2, and the light transmission layer TPL may be curved. For example, an upper surface of each of the first light conversion layer QDL1, the second light conversion layer QDL2, and the light transmission layer TPL may include a curved surface in the shape of a lens (e.g., a convex lens). Accordingly, the light output efficiency of the subpixels SPX1 through SPX3 can be increased. However, the present disclosure is not limited thereto, and the upper surface of at least one of the first light conversion layer QDL1, the second light conversion layer QDL2, and the light transmission layer TPL may also be substantially flat. The shape and/or size (e.g., area, height, or volume) of each of the first light conversion layer QDL1, the second light conversion layer QDL2, and the light transmission layer TPL may vary according to embodiments. In one or more embodiments, the light output characteristics of the subpixels SPX can be adjusted or changed by adjusting the shapes or sizes of the first light conversion layer QDL1, the second light conversion layer QDL2, and the light transmission layer TPL.

The light blocking layer BM may be around (e.g., may surround) the first light conversion layer QDL1, the second light conversion layer QDL2, and the light transmission layer TPL. A height of the light blocking layer BM may be substantially equal or similar to heights of the first light conversion layer QDL1, the second light conversion layer QDL2, and the light transmission layer TPL, but the present disclosure is not limited thereto.

The light blocking layer BM may be a single layer or a multilayer. For example, the light blocking layer BM may be a single layer or may be a multilayer including a first light blocking layer BM1 and a second light blocking layer BM2 as in the embodiment of FIG. 6.

The light blocking layer BM may include vertical side surfaces or may include inclined side surfaces as in the embodiment of FIG. 6. The shape, height, or structure of the light blocking layer BM may vary according to embodiments.

The display panels 100 according to one or more embodiments may or may not include the reflective layer RF disposed on the light blocking layer BM. For example, as illustrated in FIG. 8, the third capping layer CAP3 may be directly disposed on a second capping layer CAP2 covering the light blocking layer BM, or as illustrated in FIG. 9, the reflective layer RF and the third capping layer CAP3 may be sequentially disposed on the second capping layer CAP2. The reflective layer RF may cover at least the side surfaces of the light blocking layer BM. For example, the reflective layer RF may cover the side and upper surfaces of the light blocking layer BM.

A fifth organic layer 213, color filters CF1 through CF3, and a sixth organic layer 214 may be disposed on the third capping layer CAP3.

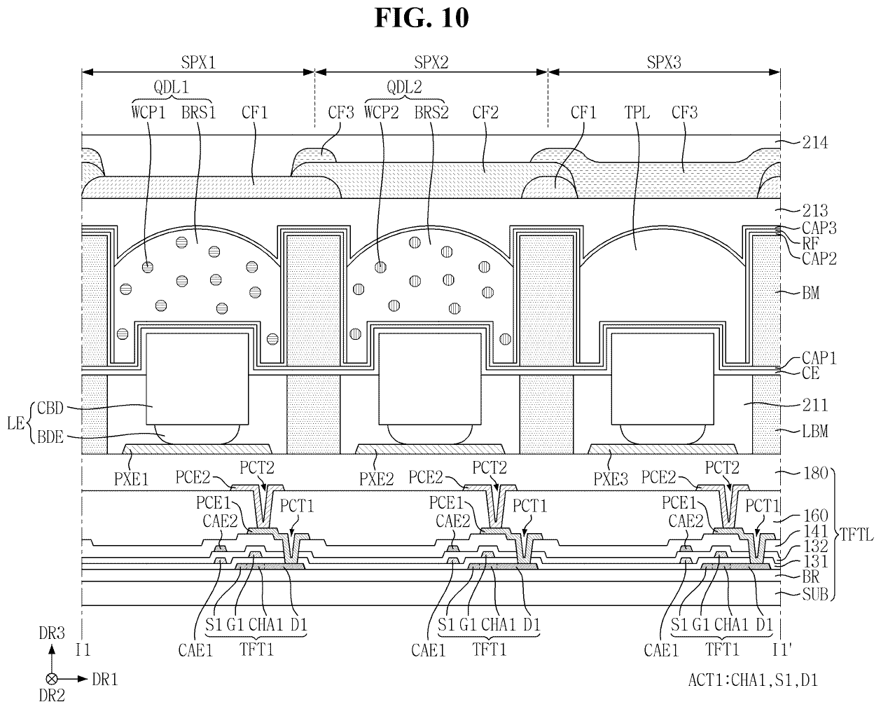

FIG. 10 is a cross-sectional view illustrating an example of a cross section of a display panel 100 corresponding to the line I1-I1′ of FIG. 5.

The embodiment of FIG. 10 is different from the embodiment of FIG. 9 in that the display panel 100 additionally includes a lower light blocking layer LBM. In the description of the embodiments of FIG. 10 and subsequent drawings, descriptions overlapping those of the previously described embodiments will be omitted.

Referring to FIG. 10, the display panel 100 may further include the lower light blocking layer LBM overlapped by a light blocking layer BM. The lower light blocking layer LBM may be disposed below the light blocking layer BM and may partially be around (e.g., may surround) side surfaces of light emitting elements LE. For example, the lower light blocking layer LBM may be around (e.g., may surround) a lower portion of each light emitting element LE (e.g., a portion disposed below a height of a third organic layer 211).

In one or more embodiments, the light blocking layer BM and the lower light blocking layer LBM may have substantially the same width and shape (e.g., planar shape) and may overlap each other. Alternatively, the light blocking layer BM and the lower light blocking layer LBM may have different widths and/or shapes and may at least partially overlap each other.

The light blocking layer BM and the lower light blocking layer LBM may include the same light blocking material or may include different light blocking materials. In one or more embodiments, the lower light blocking layer LBM may be made of an organic layer such as acryl resin, epoxy resin, phenolic resin, polyamide resin, and/or polyimide resin and may include a light blocking material. For example, the lower light blocking layer LBM may include an inorganic black pigment such as carbon black and/or an organic black pigment.

FIG. 11 is a detailed cross-sectional view of an example of an area B of FIG. 8. For example, FIG. 11 shows a light emitting element LE including a bonding electrode BDE.

Referring to FIG. 11, the light emitting element LE may include a body portion CBD and the bonding electrode BDE. In one or more embodiments, the light emitting element LE may further include a first reflective layer RFL1 disposed between the body portion CBD and the bonding electrode BDE.

The body portion CBD may include the first semiconductor layer SEM1, the active layer MQW, and the second semiconductor layer SEM2 disposed sequentially along a direction (e.g., the third direction DR3). In one or more embodiments, the body portion CBD may further include a conductive layer E1 disposed on a surface (e.g., a lower surface) of the first semiconductor layer SEM1 and a protective layer INS covering side surfaces (e.g., outer peripheral surfaces) of the conductive layer E1, the first semiconductor layer SEM1, the active layer MQW, and the second semiconductor layer SEM2.

In one or more embodiments, the conductive layer E1 may have a shape and/or size corresponding to those of the first semiconductor layer SEM1, the active layer MQW, and the second semiconductor layer SEM2. For example, the conductive layer E1 may be etched and patterned together with the first semiconductor layer SEM1, the active layer MQW, and the second semiconductor layer SEM2 on a manufacturing substrate for manufacturing light emitting elements LE (e.g., a semiconductor substrate for growing semiconductor layers). Accordingly, the conductive layer E1 may have a planar shape and size corresponding to the planar shape and size (e.g., area) of each of the first semiconductor layer SEM1, the active layer MQW, and the second semiconductor layer SEM2. However, the shape and/or size of the conductive layer E1 may vary according to embodiments. The conductive layer E1 may include molybdenum (Mo), aluminum (Al), chromium (Cr), gold (Au), titanium (Ti), nickel (Ni), neodymium (Nd), and/or copper (Cu). Alternatively, the conductive layer E1 may include a transparent conductive material such as metal oxide.

In one or more embodiments, the protective layer INS may further cover the conductive layer E1. For example, the protective layer INS may cover the side surfaces (e.g., outer peripheral surfaces) of the conductive layer E1, the first semiconductor layer SEM1, the active layer MQW, and the second semiconductor layer SEM2.

In one or more embodiments, the protective layer INS may partially cover a lower surface of the conductive layer E1. For example, the protective layer INS may cover an edge portion of the lower surface of the conductive layer E1 and may include an opening exposing a central portion of the conductive layer E1. However, the present disclosure is not limited thereto. For example, the protective layer INS may cover only the side surfaces (e.g., outer peripheral surfaces) of the conductive layer E1 or may not cover the conductive layer E1.

In one or more embodiments, the body portion CBD may have a quadrangular cross-sectional shape such as a square, rectangular, and/or trapezoidal shape. For example, the body portion CBD may be a vertical micro-LED chip having a square or rectangular cross-sectional shape. Alternatively, the body portion CBD may have a reverse-tapered (or tapered) trapezoidal cross-sectional shape as in the embodiment of FIG. 7. The type, shape, and/or size of the body portion CBD may vary according to embodiments.

The bonding electrode BDE may include a conductive material (e.g., a bonding metal) suitable for bonding. In one or more embodiments, the bonding electrode BDE may be disposed on a lower surface of the first reflective layer RFL1 and may be electrically connected to the conductive layer E1 through the first reflective layer RFL1. The bonding electrode BDE may be bonded onto each pixel electrode (e.g., the first pixel electrode PXE1, the second pixel electrode PXE2, and/or the third pixel electrode PXE3) and electrically connected to the pixel electrode.

The first reflective layer RFL1 may be disposed on a lower surface of the body portion CBD. The first reflective layer RFL1 may include a metal with high light reflectivity. For example, the first reflective layer RFL1 may be composed of at least one metal layer including at least one of metals with high reflectivity, such as aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir) and/or chromium (Cr), and/or another reflective material. In one or more embodiments, the first reflective layer RFL1 may be a multilayer composed of a reflective metal layer and a conductive bonding layer disposed on at least one surface of the reflective metal layer, but the present disclosure is not limited thereto.

Light generated in the light emitting element LE and travelling toward the bottom of the body portion CBD may be reflected by the first reflective layer RFL1 toward the top of the light emitting element LE. Accordingly, the light output efficiency of the light emitting element LE can be increased.

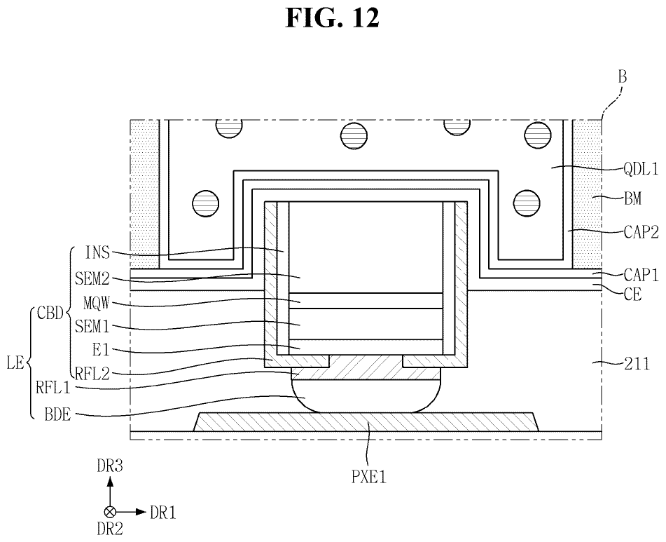

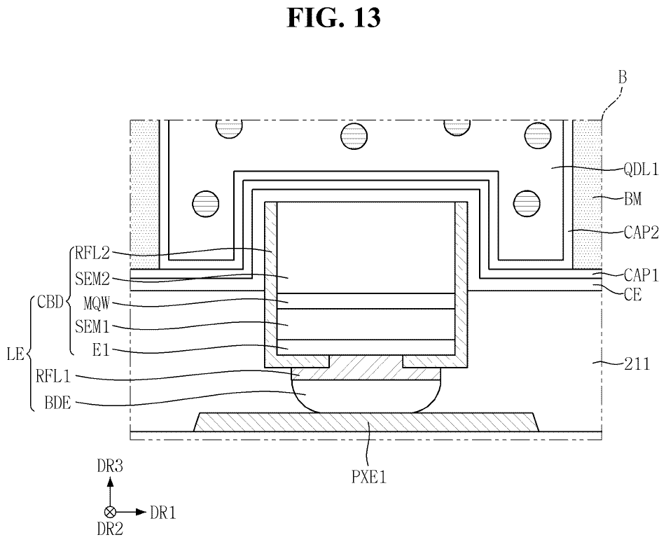

FIG. 12 is a detailed cross-sectional view of an example of the area B of FIG. 8. FIG. 13 is a detailed cross-sectional view of an example of the area B of FIG. 8.

For example, FIGS. 12 and 13 show a light emitting element LE including a

second reflective layer RFL2. In addition, FIGS. 12 and 13 show different embodiments in relation to a protective layer INS.

Referring to FIGS. 12 and 13, a body portion CBD may further include the second reflective layer RFL2 covering side surfaces of a conductive layer E1, the first semiconductor layer SEM1, the active layer MQW, and the second semiconductor layer SEM2.

The second reflective layer RFL2 may include a distributed Bragg reflector including at least one pair of a first layer (e.g., a low refractive index layer) and a second layer (e.g., a high refractive index layer) disposed sequentially or alternately and having different refractive indices. The second reflective layer RFL2 may reflect light generated in the light emitting element LE and travelling in the lateral direction of the body portion CBD.

In one or more embodiments, the second reflective layer RFL2 may be composed of multiple layers of insulating layers including an insulating material. For example, the second reflective layer RFL2 may include inorganic layers (e.g., inorganic insulating layers made of silicon nitride (SiNₓ), silicon oxynitride (SiON), silicon oxide (SiOₓ), titanium oxide (TiOₓ), and/or aluminum oxide (AlOₓ)).

In one or more embodiments, as illustrated in FIG. 12, the body portion CBD may include the protective layer INS covering the side surfaces (e.g., outer peripheral surfaces) of the conductive layer E1, the first semiconductor layer SEM1, the active layer MQW and the second semiconductor layer SEM2, and the second reflective layer RFL2 may be disposed on an outer surface (e.g., outer peripheral surfaces) of the protective layer INS. For example, the second reflective layer RFL2 may cover side surfaces (e.g., outer peripheral surfaces) of the protective layer INS.

Alternatively, the body portion CBD may not include the protective layer INS. For example, as illustrated in FIG. 13, the second reflective layer RFL2 may directly cover the side surfaces (e.g., outer peripheral surfaces) of the conductive layer E1, the first semiconductor layer SEM1, the active layer MQW, and the second semiconductor layer SEM2. The second reflective layer RFL2 may not only reflect light generated in the light emitting element LE and travelling in the lateral direction of the body portion CBD, but also protect the conductive layer E1, the first semiconductor layer SEM1, the active layer MQW, and the second semiconductor layer SEM2.

In one or more embodiments, the second reflective layer RFL2 may partially cover a lower surface of the conductive layer E1. For example, the second reflective layer RFL2 may cover an edge portion of the lower surface of the conductive layer E1 and may include an opening exposing a central portion of the conductive layer E1. On the lower surface of the conductive layer E1, a portion of a first reflective layer RFL1, and a portion of the second reflective layer RFL2 may overlap each other. The side and lower surfaces of the conductive layer E1, the first semiconductor layer SEM1, the active layer MQW, and the second semiconductor layer SEM2 may be covered with the first reflective layer RFL1 and/or the second reflective layer RFL2.

Accordingly, light generated in the light emitting element LE and travelling toward the bottom and sides of the body portion CBD may be reflected by the first reflective layer RFL1 and the second reflective layer RFL2 toward the top of the light emitting element LE. Accordingly, the amount of light emitted through a light output surface of the light emitting element LE (e.g., an upper surface of the body portion CBD) can be further increased. Accordingly, the light output efficiency of the light emitting element LE and a subpixel SPX including the light emitting element LE can be effectively improved.

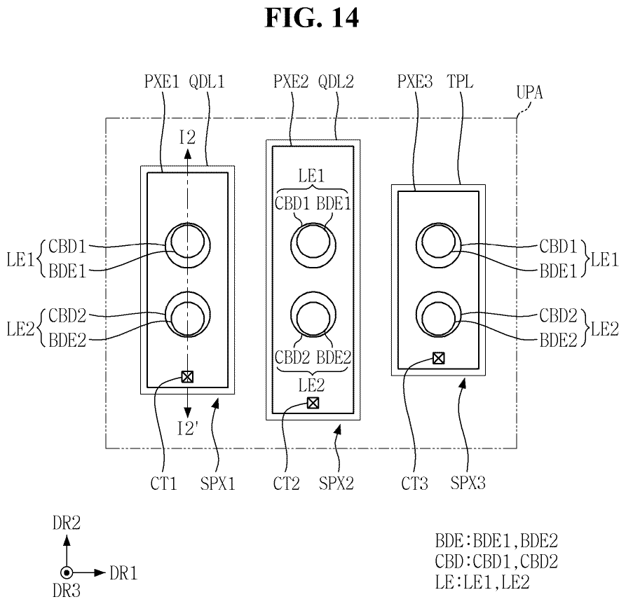

FIG. 14 is a layout view of a pixel PX of a display area according to one or more embodiments. For example, FIG. 14 shows a unit pixel area UPA of a pixel PX including light emitting elements LE, each including a bonding electrode BDE.

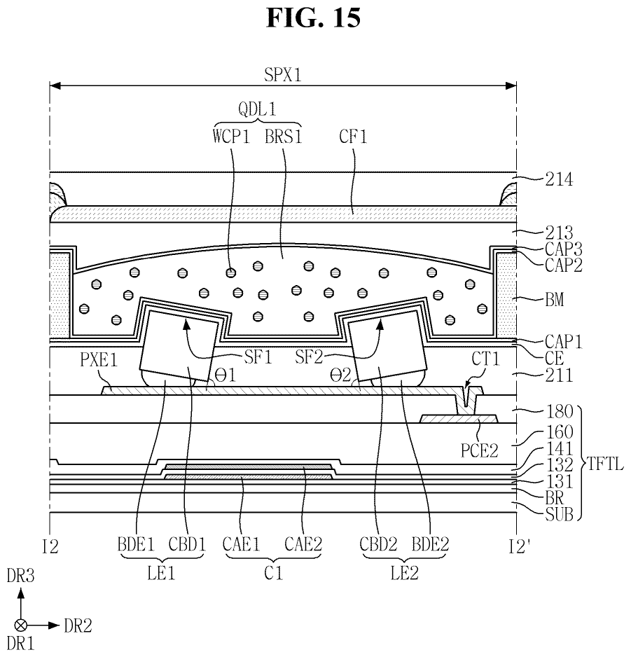

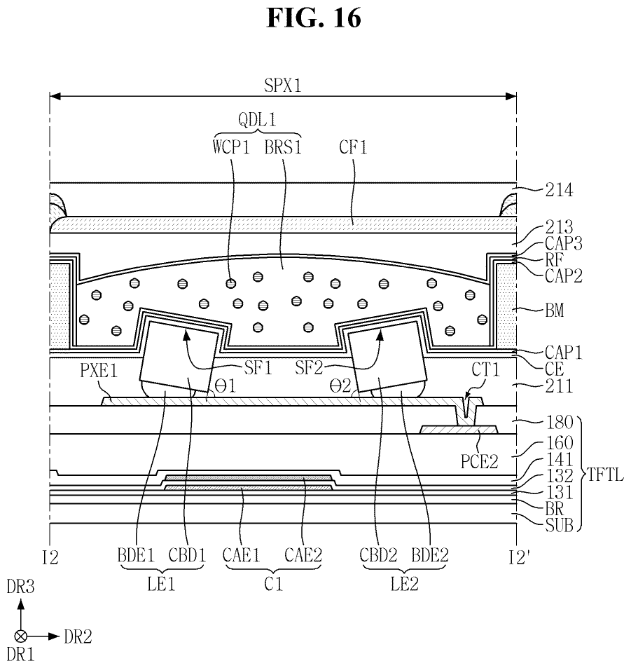

FIG. 15 is a cross-sectional view illustrating an example of a cross section of a display panel 100 corresponding to the line I2-I2′ of FIG. 14. FIG. 16 is a cross-sectional view illustrating an example of a cross section of a display panel 100 corresponding to the line I2-I2′ of FIG. 14. For example, FIGS. 15 and 16 show a cross section of a subpixel SPX, for example, a first subpixel SPX1 of FIG. 14 and show different embodiments in relation to a reflective layer RF. For example, FIG. 15 shows a display panel 100 which does not include the reflective layer RF, and FIG. 16 shows a display panel 100 which includes the reflective layer RF.

In FIGS. 15 and 16, a capacitor C1 and a second source connection electrode PCE2 are shown as an example of elements that can be disposed in a thin-film transistor layer TFTL. The elements that can be disposed in the thin-film transistor layer TFTL within a subpixel SPX may vary according to the pixel circuit of the subpixel SPX or the design structure of the thin-film transistor layer TFTL.

Referring to FIGS. 14 through 16, each subpixel SPX may include a plurality of light emitting elements LE. For example, the first subpixel SPX1, the second subpixel SPX2, and the third subpixel SPX3 may each include a first light emitting element LE1 and a second light emitting element LE2. The first light emitting element LE1 and the second light emitting element LE2 of each subpixel SPX may be disposed along the second direction DR2, but the present disclosure is not limited thereto. The first light emitting element LE1 and the second light emitting element LE2 may be light emitting elements LE of substantially the same type, structure, and/or size, but the present disclosure is not limited thereto.

Each light emitting element LE may include a body portion CBD and a bonding electrode BDE. For example, the first light emitting element LE1 may include a first body portion CBD1 including the first semiconductor layer SEM1, the active layer MQW, and the second semiconductor layer SEM2, and a first bonding electrode BDE1 disposed on a lower surface of the first body portion CBD1. The second light emitting element LE2 may include a second body portion CBD2 including the first semiconductor layer SEM1, the active layer MQW, and the second semiconductor layer SEM2, and a second bonding electrode BDE2 disposed on a lower surface of the second body portion CBD2.

Each light emitting element LE may further include at least one of the first reflective layer RFL1 and the second reflective layer RFL2 described in the embodiments of FIGS. 11 through 13. The first reflective layer RFL1 may be disposed between the body portion CBD and the bonding electrode BDE. The second reflective layer RFL2 may be regarded as an element included in the body portion CBD or may be regarded as an element disposed on an outer surface (e.g., an outer peripheral surface) of the body portion CBD separately from the body portion CBD.

Each light emitting element LE may be disposed on a pixel electrode of a subpixel SPX. For example, the first light emitting element LE1 and the second light emitting element LE2 of the first subpixel SPX1 may be disposed on a first pixel electrode PXE1. The first light emitting element LE1 and the second light emitting element LE2 of the second subpixel SPX2 may be disposed on a second pixel electrode PXE2. The first light emitting element LE1 and the second light emitting element LE2 of the third subpixel SPX3 may be disposed on a third pixel electrode PXE3.

At least one of the light emitting elements LE of each subpixel SPX may be tilted on a pixel electrode. For example, at least one of the light emitting elements LE of each subpixel SPX may be bonded onto a pixel electrode at an angle to the pixel electrode.

In an embodiment, at least one of the light emitting elements LE of each subpixel SPX may be disposed on a pixel electrode at an angle of ±5° or more with respect to a direction (e.g., the third direction DR3) perpendicular to the pixel electrode. For example, an angle formed by the body portion CBD of at least one of the light emitting elements LE of each subpixel SPX and a pixel electrode of the subpixel SPX may be 85° or less or 95° or more. Accordingly, at least one of the light emitting elements LE may be substantially tilted in each subpixel SPX.

In one or more embodiments, in each of the subpixels SPX constituting the pixel PX, at least one light emitting element LE may be disposed or bonded at an angle on a pixel electrode. For example, at least one of the body portions CBD of the first light emitting element LE1 and the second light emitting element LE2 of the first subpixel SPX1 may be disposed not substantially perpendicularly but at an angle of ±5° or more to the first pixel electrode PXE1. Similarly, at least one of the body portions CBD of the first light emitting element LE1 and the second light emitting element LE2 of the second subpixel SPX2 may be disposed not substantially perpendicularly but at an angle of ±5° or more to the second pixel electrode PXE2. At least one of the body portions CBD of the first light emitting element LE1 and the second light emitting element LE2 of the third subpixel SPX3 may be disposed not substantially perpendicularly but at an angle of ±5° or more to the third pixel electrode PXE3.

However, the present disclosure is not limited thereto. For example, at least one light emitting element LE may be tilted in at least one of the subpixels SPX constituting the pixel PX, and the light emitting elements LE may be disposed substantially perpendicularly in the other subpixels SPX.

In one or more embodiments, the first light emitting element LE1 and the second light emitting element LE2 of each subpixel SPX may be tilted toward the center of the subpixel SPX (e.g., the center of an emission area of each subpixel SPX in which a pixel electrode and a first light conversion layer QDL1, a second light conversion layer QDL2, or a light transmission layer TPL are disposed and which is surrounded by a light blocking layer BM). For example, the first light emitting element LE1 and the second light emitting element LE2 of the first subpixel SPX1 may be disposed on the first pixel electrode PXE1 not substantially perpendicularly but at an angle of ±5° or more toward the center of the first subpixel SPX1. In this case, a central axis of each of the body portions CBD of the first light emitting element LE1 and the second light emitting element LE2 may be tilted by 35 5° or more with respect to a direction (e.g., the third direction DR3) perpendicular to the first pixel electrode PXE1.

In one or more embodiments, when the first light emitting element LE1 and the second light emitting element LE2 are tilted toward the center of a subpixel SPX, angles formed between central axes of the first light emitting element LE1 and the second light emitting element LE2 and the third direction DR3 or directions in which the central axes of the first light emitting element LE1 and the second light emitting element LE2 are tilted with respect to the third direction DR3 may be different. For example, a central axis of the first body portion CBD1 of the first light emitting element

LE1 may be tilted by 30 5° or more with respect to the third direction DR3, and a central axis of the second body portion CBD2 of the second light emitting element LE2 may be tilted by −5° or more with respect to the third direction DR3.

In one or more embodiments, when the body portion CBD of each of the first light emitting element LE1 and the second light emitting element LE2 has a substantially rectangular or square cross section, an angle (θ1, θ2) formed between a side surface facing the center of the first subpixel SPX1 from among side surfaces of each of the body portions CBD of the first light emitting element LE1 and the second light emitting element LE2 and the first pixel electrode PXE1 may be an acute angle of 85° or less. Conversely, an angle formed between a side surface facing the periphery of the first subpixel SPX1 from among the side surfaces of each of the body portions CBD of the first light emitting element LE1 and the second light emitting element LE2 and the first pixel electrode PXE1 may be an obtuse angle of 95° or more. Angles at which the body portions CBD of the first light emitting element LE1 and the second light emitting element LE2 are tilted may be substantially the same or different. For example, an angle at which each of the first light emitting element LE1 and the second light emitting element LE2 is tilted may be adjusted or changed in consideration of the light efficiency of each subpixel SPX or the direction in which light is to be concentrated.

In one or more embodiments, each of the first light emitting element LE1 and the second light emitting element LE2 may include a light output surface SF1 or SF2 corresponding to an upper surface of the body portion CBD. When the first light emitting element LE1 and the second light emitting element LE2 are tilted toward the center of each subpixel SPX, the light output surfaces SF1 and SF2 of the first light emitting element LE1 and the second light emitting element LE2 may be tilted toward the center of each subpixel SPX. For example, the light output surfaces SF1 and SF2 of the first light emitting element LE1 and the second light emitting element LE2 of the first subpixel SPX1 may be tilted toward the center of the first subpixel SPX1. For example, the light output surfaces SF1 and SF2 of the first light emitting element LE1 and the second light emitting element LE2 of the first subpixel SPX1 may be tilted by ±5° or more with respect to the first pixel electrode PXE1 or a plane parallel to the first pixel electrode PXE1.

Similarly, light output surfaces of the first light emitting element LE1 and the second light emitting element LE2 of the second subpixel SPX2 may be tilted toward the center of the second subpixel SPX2, and light output surfaces of the first light emitting element LE1 and the second light emitting element LE2 of the third subpixel SPX3 may be tilted toward the center of the third subpixel SPX3. In one or more embodiments, tilt directions or angle ranges of the light emitting elements LE of the subpixels SPX1 through SPX3 may be substantially equal or similar, but the present disclosure is not limited thereto.

In one or more embodiments, the direction or degree of tilt of each light emitting element LE may be adjusted by adjusting at least one of the position, shape, and/or size of the bonding electrode BDE (e.g., the area, thickness, or volume of the bonding electrode BDE) in the light emitting element LE. For example, the first bonding electrode BDE1 may be disposed more on a portion of the lower surface of the first body portion CBD1 which is close to the periphery of each subpixel SPX (e.g., an area adjacent to the light blocking layer BM). For example, in the second direction DR2, the first bonding electrode BDE1 may be disposed more toward the periphery of each subpixel SPX with respect to the central axis of the first body portion CBD1. Accordingly, the first light emitting element LE1 (or the first body portion CBD1) may be disposed or bonded at an angle toward the center of each subpixel SPX. Similarly, the second bonding electrode BDE2 may be disposed more on a portion of the lower surface of the second body portion CBD2 which is close to the periphery of each subpixel SPX. For example, in the second direction DR2, the second bonding electrode BDE2 may be disposed more toward the periphery of each subpixel SPX with respect to the central axis of the second body portion CBD2. Accordingly, the second light emitting element LE2 (or the second body portion CBD2) may be disposed or bonded at an angle toward the center of each subpixel SPX.

In one or more embodiments, a bonding electrode BDE of a light emitting element LE tilted in a subpixel SPX may have a thickness that gradually changes as the distance to the center or periphery of the subpixel SPX decreases. For example, when the first light emitting element LE1 of the first subpixel SPX1 is tilted toward the center of the first subpixel SPX1, the first bonding electrode BDE1 of the first light emitting element LE1 may have a relatively large thickness in a portion adjacent to the periphery of the first subpixel SPX1. Similarly, when the second light emitting element LE2 of the first subpixel SPX1 is tilted toward the center of the first subpixel SPX1, the second bonding electrode BDE2 of the second light emitting element LE2 may have a relatively large thickness in a portion adjacent to the periphery of the first subpixel SPX1.

In one or more embodiments, when the light emitting elements LE are formed, the bonding electrode BDE of each of the light emitting elements LE may be formed to have a thickness of 1 μm or more. Accordingly, the light emitting elements LE can be properly or smoothly bonded onto the pixel electrodes PXE1 through PXE3. In addition, the light emitting elements LE can be properly or smoothly bonded at an angle within a desired angle range. However, the thickness of the bonding electrode BDE may also be reduced during a bonding process. For example, after a light emitting element LE is bonded to a pixel electrode, the thickness of the bonding electrode BDE may be reduced to 1 μm or less, or the bonding electrode BDE may have a thickness of 1 μm or less in at least one portion (e.g., a portion with a minimum thickness).

When at least one of the light emitting elements LE of a subpixel SPX is tilted toward the center of the subpixel SPX, the amount of light travelling to the center of the subpixel SPX from among light generated from the at least one of the light emitting elements LE may increase. For example, because the light output surfaces SF1 and SF2 of the first light emitting element LE1 and the second light emitting element LE2 are tilted toward the center of the subpixel SPX, light emitted from the first light emitting element LE1 and the second light emitting element LE2 may be more concentrated toward the center of the subpixel SPX.

Due to this light concentrating effect, the light output efficiency of the subpixel SPX can be improved. For example, light absorbed by the light blocking layer BM or leaking to the thin-film transistor layer TFTL from among the light emitted from the first light emitting element LE1 and the second light emitting element LE2 can be reduced. In addition, the light emitted from the first light emitting element LE1 and the second light emitting element LE2 can be more effectively concentrated to the first light conversion layer QDL1, the second light conversion layer QDL2, or the light transmission layer TPL included in each subpixel SPX. Accordingly, the amount of light emitted from each subpixel SPX may increase.

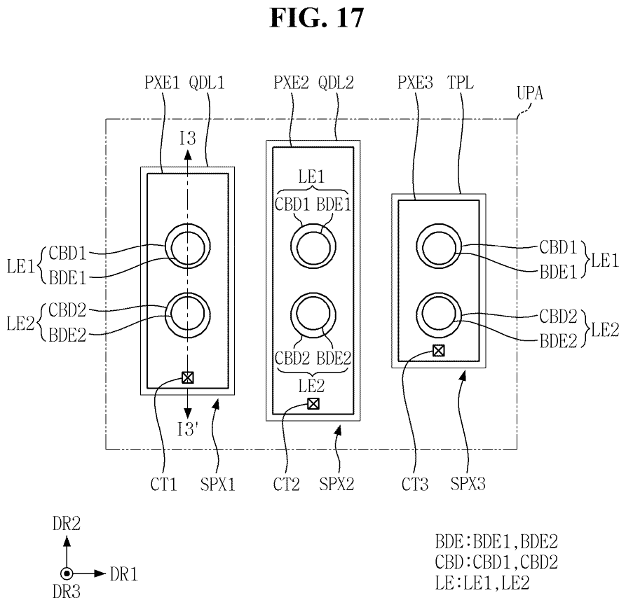

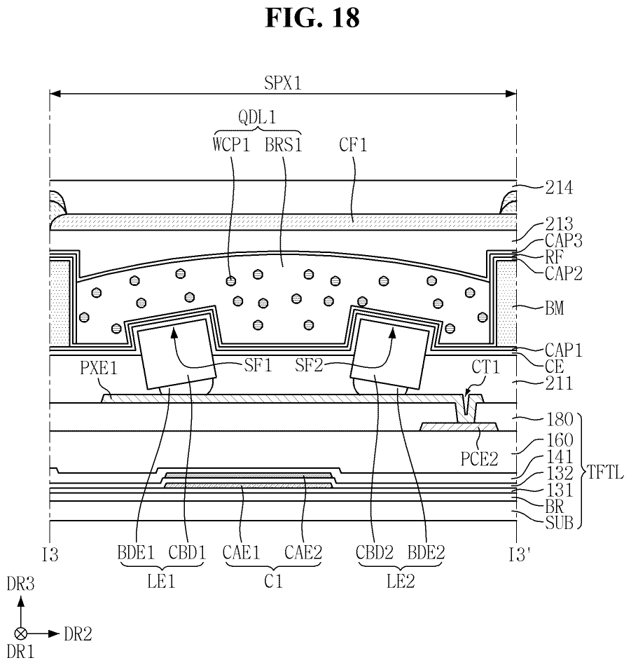

FIG. 17 is a layout view of a pixel of a display area according to one or more embodiments. FIG. 18 is a cross-sectional view illustrating an example of a cross section of a display panel corresponding to the line I3-I3′ of FIG. 17.

FIGS. 17 and 18 show an embodiment different from the embodiments of

FIGS. 14 through 16 in relation to a direction in which light emitting elements LE are tilted.

Referring to FIGS. 17 and 18, a light blocking layer BM may be around (e.g., may surround) an emission area of each subpixel SPX where a pixel electrode and light emitting elements LE are disposed, and a reflective layer RF may be disposed on the light blocking layer BM (or a second capping layer CAP2 covering the light blocking layer BM). The reflective layer RF may be disposed on side surfaces of the light blocking layer BM and may be around (e.g., may surround) the emission area of each subpixel SPX. In one or more embodiments, the reflective layer RF may also be disposed on an upper surface of the light blocking layer BM.

At least one of the light emitting elements LE of at least one subpixel SPX may be tilted on a pixel electrode. For example, at least one of the light emitting elements LE of at least one subpixel SPX may be bonded onto a pixel electrode at an angle to the pixel electrode.

In one or more embodiments, at least one of body portions CBD of a first

light emitting element LE1 and a second light emitting element LE2 of a first subpixel SPX1 may be tilted by ±5° or more with respect to the third direction DR3 which is substantially perpendicular to a first pixel electrode PXE1. In one or more embodiments, a body portion CBD of at least one of light emitting elements LE of a second subpixel SPX2 and a third subpixel SPX3 may be disposed or bonded at an angle to each pixel electrode (e.g., a second pixel electrode PXE2 and/or a third pixel electrode PXE3). For example, at least one of body portions CBD of a first light emitting element LE1 and a second light emitting element LE2 of the second subpixel SPX2 and the third subpixel SPX3 may be tilted by ±5° or more with respect to the third direction DR3.

In one or more embodiments, light output surfaces SF1 and SF2 of the light emitting elements LE disposed at an angle in the subpixels SPX may be tilted toward the periphery of the subpixels SPX. For example, the light output surfaces SF1 and SF2 of the first light emitting element LE1 and the second light emitting element LE2 of the first subpixel SPX1 may be tilted toward the reflective layer RF disposed around the first subpixel SPX1. For example, the light output surfaces SF1 and SF2 of the first light emitting element LE1 and the second light emitting element LE2 of the first subpixel SPX1 may be tilted toward the periphery of the first subpixel SPX1 by ±5° or more with respect to the first pixel electrode PXE1 or a plane parallel to the first pixel electrode PXE1. In one or more embodiments, light output surfaces of the first light emitting element LE1 and the second light emitting element LE2 of each of the second subpixel SPX2 and the third subpixel SPX3 may also be tilted by ±5° or more toward the light blocking layer BM and the reflective layer RF.

In one or more embodiments, when the first light emitting element LE1 and the second light emitting element LE2 are tilted toward the periphery of a subpixel SPX, angles formed between central axes of the first light emitting element LE1 and the second light emitting element LE2 and the third direction DR3 or directions in which the central axes of the first light emitting element LE1 and the second light emitting element LE2 are tilted with respect to the third direction DR3 may be different. For example, a central axis of a first body portion CBD1 of the first light emitting element LE1 may be tilted by −5° or more with respect to the third direction DR3, and a central axis of a second body portion CBD2 of the second light emitting element LE2 may be tilted by +5° or more with respect to the third direction DR3.

In one or more embodiments, when the body portion CBD of each of the first light emitting element LE1 and the second light emitting element LE2 has a substantially rectangular or square cross section, an angle formed between a side surface facing the center of the first subpixel SPX1 from among side surfaces of each of the body portions CBD of the first light emitting element LE1 and the second light emitting element LE2 and the first pixel electrode PXE1 may be an obtuse angle of 95° or more. Conversely, an angle formed between a side surface facing the periphery of the first subpixel SPX1 from among the side surfaces of each of the body portions CBD of the first light emitting element LE1 and the second light emitting element LE2 and the first pixel electrode PXE1 may be an acute angle of 85° or less. Angles at which the body portions CBD of the first light emitting element LE1 and the second light emitting element LE2 are tilted may be the same or different. For example, an angle at which each of the first light emitting element LE1 and the second light emitting element LE2 is tilted toward the periphery of a subpixel SPX may be adjusted or changed in consideration of the light efficiency of the subpixel SPX.

In one or more embodiments, a first bonding electrode BDE1 may be disposed more on a portion of a lower surface of the first body portion CBD1 which is close to the center of a subpixel SPX. For example, in the second direction DR2, the first bonding electrode BDE1 may be disposed more toward the center of the subpixel SPX with respect to the central axis of the first body portion CBD1. Accordingly, the first light emitting element LE1 (or the first body portion CBD1) may be disposed or bonded at an angle toward the periphery of the subpixel SPX or the reflective layer RF.

Similarly, a second bonding electrode BDE2 may be disposed on a lower surface of the second body portion CBD2 more toward the center of the subpixel SPX. Accordingly, the second light emitting element LE2 (or the second body portion CBD2) may be disposed or bonded at an angle toward the periphery of the subpixel SPX or the reflective layer RF.

In one or more embodiments, a bonding electrode BDE of a light emitting element LE tilted in a subpixel SPX may have a thickness that gradually changes as the distance to the center or periphery of the subpixel SPX decreases. For example, when the first light emitting element LE1 of the first subpixel SPX1 is tilted toward the periphery of the first subpixel SPX1, the first bonding electrode BDE1 of the first light emitting element LE1 may have a relatively large thickness in a portion close to the center of the first subpixel SPX1. Similarly, when the second light emitting element LE2 of the first subpixel SPX1 is tilted toward the periphery of the first subpixel SPX1, the second bonding electrode BDE2 of the second light emitting element LE2 may have a relatively large thickness in a portion close to the center of the first subpixel SPX1.

When at least one of the light emitting elements LE of a subpixel SPX is tilted toward the periphery of the subpixel SPX, the amount of light travelling to the reflective layer RF from among light generated from the at least one of the light emitting elements LE may increase. For example, because the light output surfaces SF1 and SF2 of the first light emitting element LE1 and the second light emitting element LE2 are tilted toward the periphery of the subpixel SPX, light emitted from the first light emitting element LE1 and the second light emitting element LE2 may be dispersed more toward the reflective layer RF.

Accordingly, the amount of light reflected by the reflective layer RF may increase, thereby improving the light output efficiency of the subpixel SPX. For example, the amount of light reflected by the reflective layer RF to enter a first light conversion layer QDL1, a second light conversion layer QDL2, or a light transmission layer TPL from among the light emitted from the first light emitting element LE1 and the second light emitting element LE2 may increase. Accordingly, the amount of light emitted from the subpixel SPX may increase.

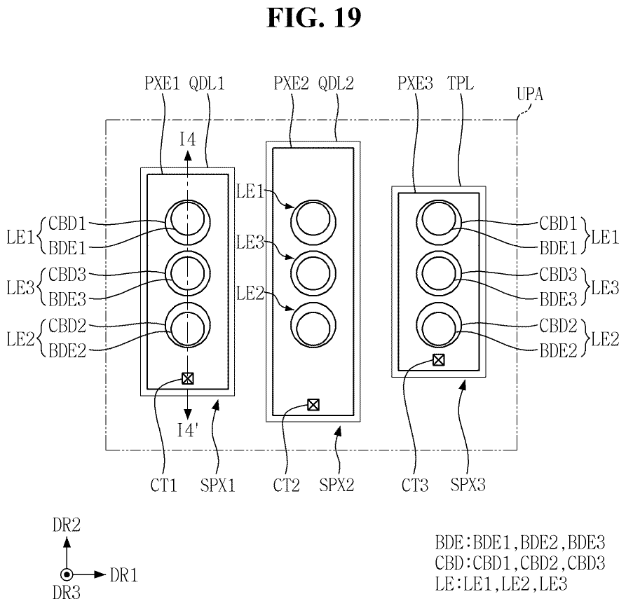

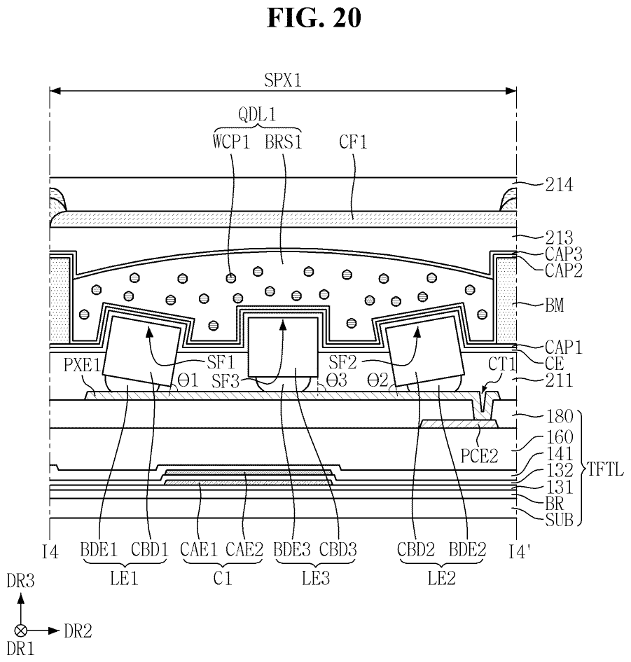

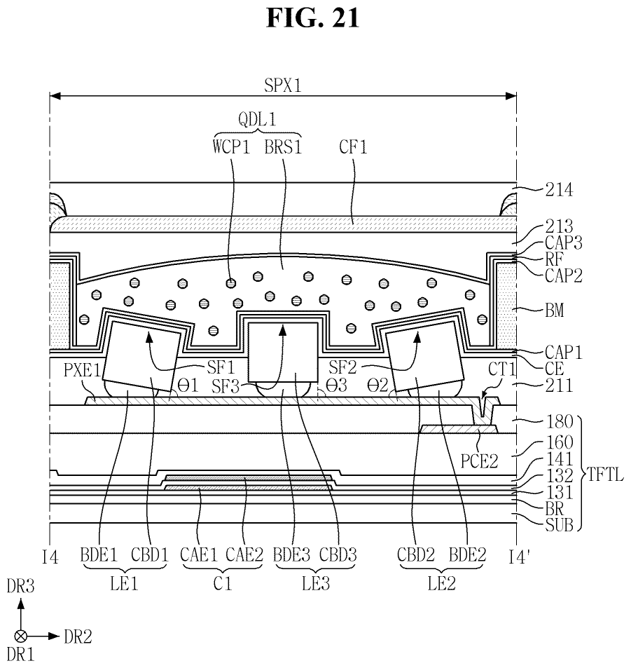

FIG. 19 is a layout view of a pixel of a display area according to one or more embodiments. FIG. 20 is a cross-sectional view illustrating an example of a cross section of a display panel corresponding to the line I4-I4′ of FIG. 19. FIG. 21 is a cross-sectional view illustrating an example of a cross section of a display panel corresponding to the line I4-I4′ of FIG. 19.

FIGS. 19 through 21 show embodiments different from the embodiments of FIGS. 14 through 16 in relation to the number of light emitting elements LE disposed in each subpixel SPX1, SPX2, and/or SPX3. FIGS. 20 and 21 show different embodiments in relation to a reflective layer RF. For example, a display panel 100 may or may not include the reflective layer RF.

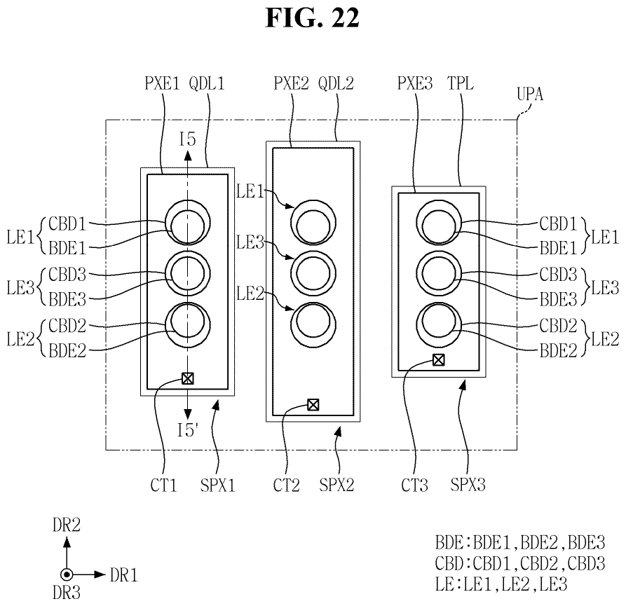

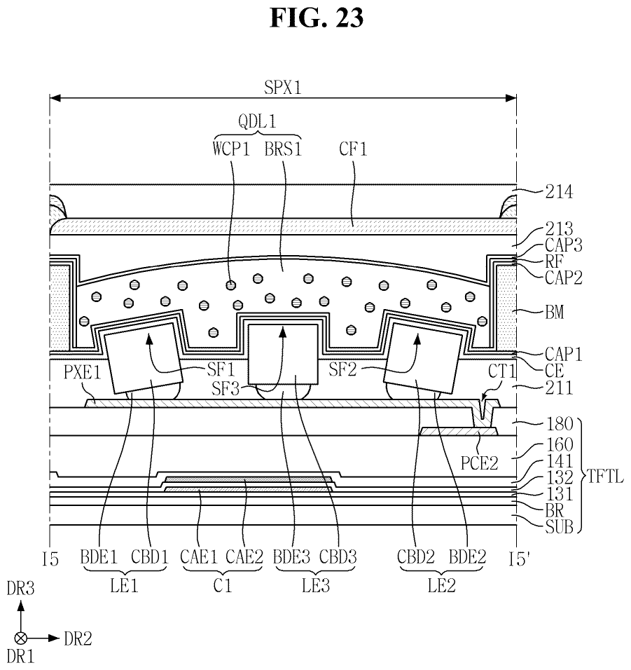

FIG. 22 is a layout view of a pixel of a display area according to one or more embodiments. FIG. 23 is a cross-sectional view illustrating an example of a cross section of a display panel corresponding to the line I5-I5′ of FIG. 22.

FIGS. 22 and 23 show an embodiment different from the embodiment of FIGS. 17 and 18 in relation to the number of light emitting elements LE.

Referring to FIGS. 19 through 23, subpixel SPX1 through SPX3 may each include three or more light emitting elements LE. For example, each of the subpixels SPX1 through SPX3 may further include a third light emitting element LE3. For example, a first subpixel SPX1 may include a first light emitting element LE1, a second light emitting element LE2, and a third light emitting element LE3 disposed on a first pixel electrode PXE1, a second subpixel SPX2 may include a first light emitting element LE1, a second light emitting element LE2, and a third light emitting element LE3 disposed on a second pixel electrode PXE2, and a third subpixel SPX3 may include a first light emitting element LE1, a second light emitting element LE2, and a third light emitting element LE3 disposed on a third pixel electrode PXE3.

The third light emitting element LE3 may be disposed at the center of a subpixel SPX compared with the first light emitting element LE1 and the second light emitting element LE2. For example, in each subpixel SPX, the third light emitting element LE3 may be disposed between the first light emitting element LE1 and the second light emitting element LE2.

The third light emitting element LE3 may include a third body portion CBD3 and a third bonding electrode BDE3. The third body portion CBD3 may include the first semiconductor layer SEM1, the active layer MQW, and the second semiconductor layer SEM2. The third bonding electrode BDE3 may be disposed on a lower surface of the third body portion CBD3. In one or more embodiments, the third light emitting element LE3 may further include at least one of the first reflective layer RFL1 and/or the second reflective layer RFL2 described in the embodiments of FIGS. 11 through 13.

In one or more embodiments, the third light emitting element LE3 may be disposed substantially perpendicularly to a pixel electrode. For example, the third light emitting element LE3 of the first subpixel SPX1 may be disposed substantially perpendicularly on the first pixel electrode PXE1, the third light emitting element LE3 of the second subpixel SPX2 may be disposed substantially perpendicularly on the second pixel electrode PXE2, and the third light emitting element LE3 of the third subpixel SPX3 may be disposed substantially perpendicularly on the third pixel electrode PXE3. For example, a central axis of the third body portion CBD3 of the third light emitting element LE3 may be located within an angle range of ±5° with respect to the third direction DR3. In one or more embodiments, when the third body portion CBD3 has a substantially rectangular or square cross section, an angle θ3 formed by a side surface of the third body portion CBD3 and a pixel electrode may be within the range of 85 to 95°. For example, the angle formed between the side surface of the third body portion CBD3 and the pixel electrode may be 90° or may be in the range of 86 to 94°.

In one or more embodiments, the third bonding electrode BDE3 of the third light emitting element LE3 may have overall a uniform thickness. Accordingly, the third light emitting element LE3 can be stably placed or bonded on a pixel electrode without being substantially at an angle with respect to the third direction DR3.

The third light emitting element LE3 may include a light output surface SF3 corresponding to an upper surface of the third body portion CBD3. In one or more embodiments, the light output surface SF3 of the third light emitting element LE3 may be disposed toward the top of a subpixel SPX. For example, the light output surface SF3 of the third light emitting element LE3 disposed in each of the subpixels SPX1 through SPX3 may face the third direction DR3.

In the embodiments of FIGS. 19 through 21, the light emitting elements LE of a subpixel SPX may be disposed toward the center of the subpixel SPX. For example, the light output surfaces SF1 through SF3 of the first light emitting element LE1, the second light emitting element LE2, and the third light emitting element LE3 may be disposed toward the center of a first light conversion layer QDL1, a second light conversion layer QDL2, or a light transmission layer TPL of a subpixel SPX.

Accordingly, light emitted from the light emitting elements LE of the subpixel SPX can be concentrated to the center of the subpixel SPX, and the light output efficiency of the subpixel SPX can be improved by this light concentrating effect.

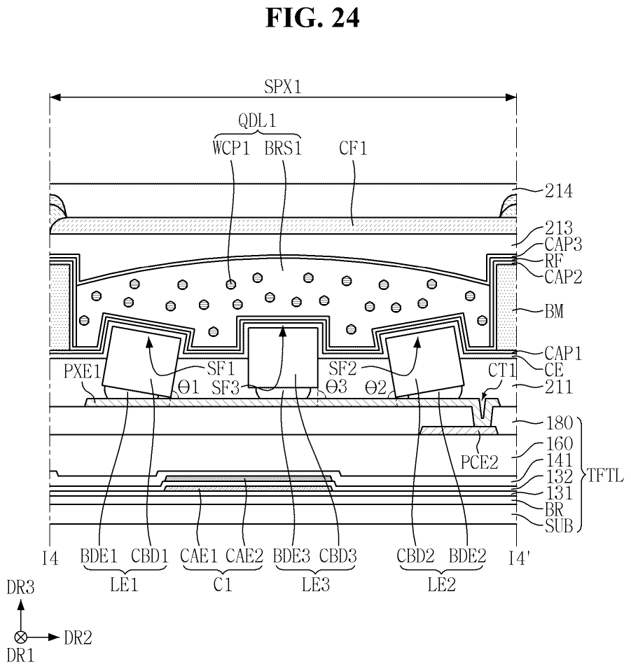

In the embodiment of FIGS. 22 and 23, light emitting elements LE disposed close to the periphery of a subpixel SPX from among light emitting elements LE of the subpixel SPX may be disposed toward the periphery of the subpixel SPX. For example, the light output surfaces SF1 and SF2 of the first light emitting element LE1 and the second light emitting element LE2 may be tilted more toward the reflective layer RF. Accordingly, the amount of light reflected by the reflective layer RF may increase, thereby improving the light output efficiency of the subpixel SPX. FIG. 24 is a cross-sectional view illustrating an example of a cross section of

a display panel corresponding to the line I4-I4′ of FIG. 19. FIG. 24 shows an embodiment different from the previously described embodiments (e.g., the embodiment of FIG. 21) in relation to a first light emitting element LE1 and a second light emitting element LE2.

Referring to FIG. 24, at least one of body portions CBD1 and CBD2 of the first light emitting element LE1 and the second light emitting element LE2 disposed in at least one subpixel SPX may contact a pixel electrode of the subpixel SPX. For example, the body portions CBD1 and CBD2 of the first light emitting element LE1 and the second light emitting element LE2 of a first subpixel SPX1 may contact a first pixel electrode PXE1. Similarly, the body portions CBD1 and CBD2 of the first light emitting element LE1 and the second light emitting element LE2 of a second subpixel SPX2 may contact a second pixel electrode PXE2, and the body portions CBD1 and CBD2 of the first light emitting element LE1 and the second light emitting element LE2 of a third subpixel SPX3 may contact a third pixel electrode PXE3. For example, each of the light emitting elements LE may or may not contact a pixel electrode depending on the thickness or volume of a bonding electrode BDE included in the light emitting element LE, the pressure applied during a bonding process, or the angle at which the light emitting element LE is tilted. In one or more embodiments, the body portions CBD1 and CBD2 of the first light emitting element LE1 and the second light emitting element LE2 may be brought into contact with a pixel electrode of a corresponding subpixel SPX, so that the first light emitting element LE1 and the second light emitting element LE2 can be supported more stably.

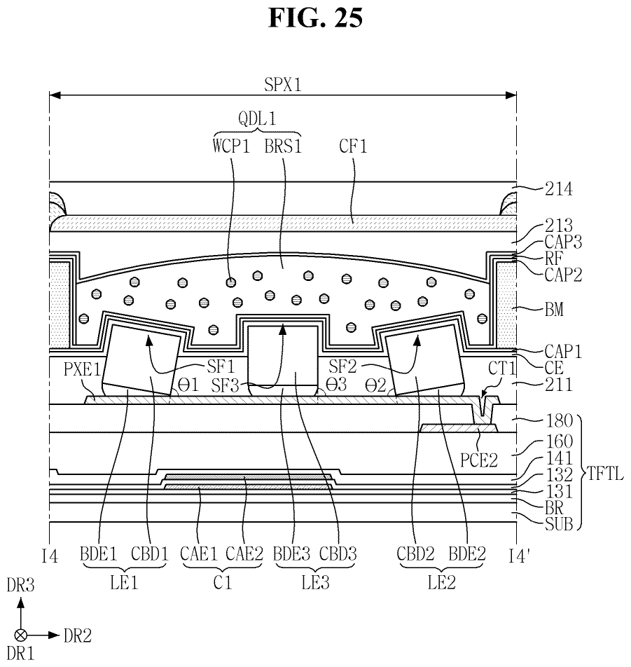

FIG. 25 is a cross-sectional view illustrating an example of a cross section of

a display panel corresponding to the line I4-I4′ of FIG. 19. FIG. 25 shows an embodiment different from the previously described embodiments (e.g., the embodiment of FIG. 24) in relation to bonding electrodes BDE of light emitting elements LE.

Referring to FIG. 25, a bonding electrode BDE of at least one light emitting element LE may be disposed on the entire lower surface of a body portion CBD. For example, a first bonding electrode BDE1 of a first light emitting element LE1 may be disposed on the entire lower surface of a first body portion CBD1. Similarly, a second bonding electrode BDE2 of a second light emitting element LE2 may be disposed on the entire lower surface of a second body portion CBD2, and a third bonding electrode BDE3 of a third light emitting element LE3 may be disposed on the entire lower surface of a third body portion CBD3. For example, the bonding electrode BDE of each light emitting element LE may melt and spread on the entire lower surface of the body portion CBD depending on the thickness or volume of the bonding electrode BDE included in the light emitting element LE, the pressure or temperature during a bonding process, etc.

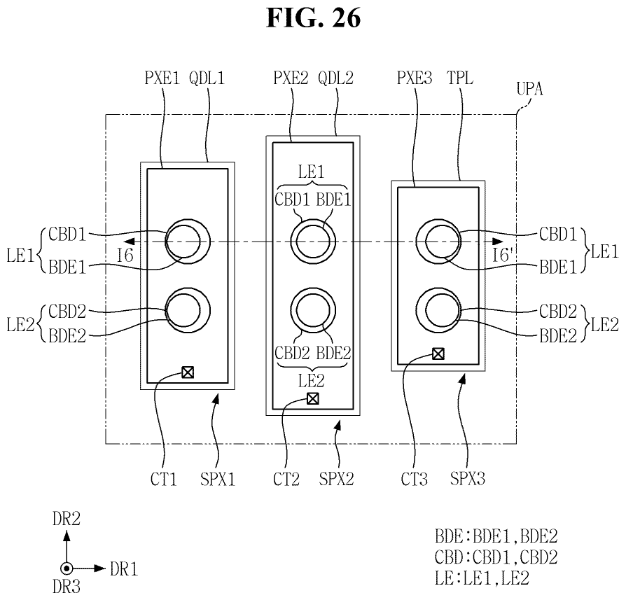

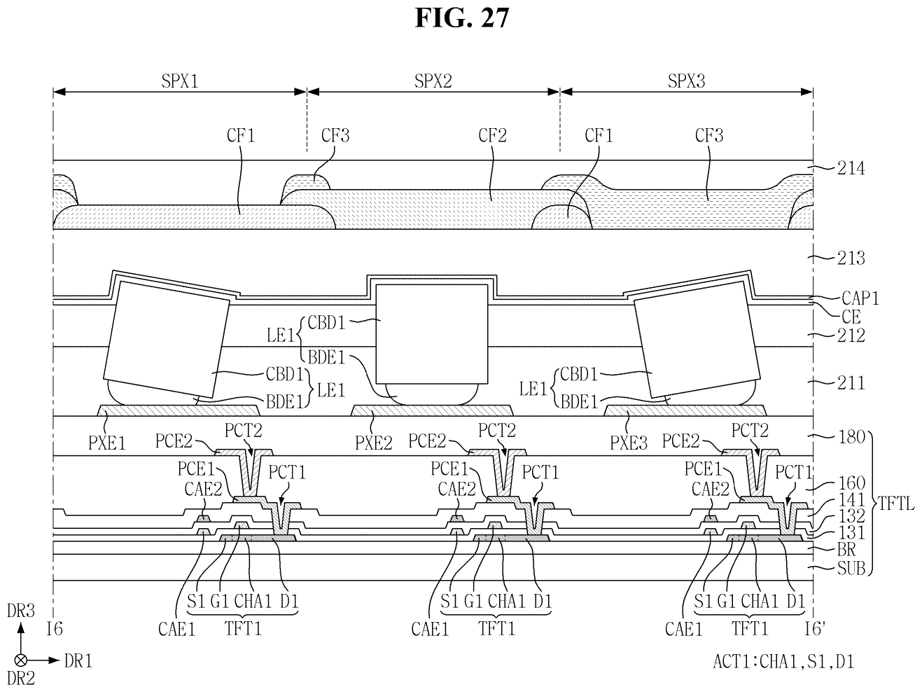

FIG. 26 is a layout view of a pixel of a display area according to one or more embodiments. FIG. 27 is a cross-sectional view illustrating an example of a cross section of a display panel corresponding to the line I1-I6′ of FIG. 26. FIGS. 26 and 27 show an embodiment of a display panel 100 in which subpixels SPX1 through SPX3 of each pixel PX include light emitting elements LE that emit light of different colors.

Referring to FIGS. 26 and 27, a first subpixel SPX1, a second subpixel SPX2, and a third subpixel SPX3 may include light emitting elements LE that emit light of a first color, light of a second color, and light of a third color. For example, a first light emitting element LE1 and a second light emitting element LE2 of the first subpixel SPX1 may be first color light emitting elements (e.g., red light emitting elements) that emit light of the first color. A first light emitting element LE1 and a second light emitting element LE2 of the second subpixel SPX2 may be second color light emitting elements (e.g., green light emitting elements) that emit light of the second color. A first light emitting element LE1 and a second light emitting element LE2 of the third subpixel SPX3 may be third color light emitting elements (e.g., blue light emitting elements) that emit light of the third color.

Accordingly, the pixel PX may not include a first light conversion layer QDL1,

a second light conversion layer QDL2, and a light transmission layer TPL. For example, a fifth organic layer 213, color filters CF1 through CF3, and a sixth organic layer 214 may be sequentially disposed on a first capping layer CAP1 covering a common electrode CE.

FIG. 27 illustrates a display panel 110 not including the light blocking layer BM according to the previously described embodiments. However, even if the pixel PX does not include the first light conversion layer QDL1 and the second light conversion layer QDL2, in one or more embodiments, the display panel 110 may further include at least one of the light blocking layer BM and the light transmission layer TPL. For example, a third organic layer 211 may be disposed on side surfaces of the light emitting elements LE according to the embodiment of FIG. 27, and the common electrode CE and the first capping layer CAP1 may be disposed on the third organic layer 211 and the fourth organic layer 212. In addition, in one or more embodiments, the light blocking layer BM, a second capping layer CAP2, the light transmission layer TPL, a third capping layer CAP3, the fifth organic layer 213, the color filters CF1 through CF3, and the sixth organic layer 214 may be sequentially disposed on the first capping layer CAP1. In the display panel 110 including the light emitting elements LE according to the embodiment of FIG. 27, in one or more embodiments, each of the first light conversion layer QDL1 and the second light conversion layer QDL2 disposed in the first subpixel SPX1 and the second subpixel SPX2 in FIG. 8 may be formed as the light transmission layer TPL that does not include wavelength conversion particles WCP1 or WCP2.

Each subpixel SPX may include at least one light emitting element LE disposed on a pixel electrode. In one or more embodiments, each subpixel SPX may include a plurality of light emitting elements LE including a first light emitting element LE1 and a second light emitting element LE2.

In one or more embodiments, the light emitting elements LE of the subpixels SPX1 through SPX3 may be disposed to face the center of a unit pixel area UPA where a corresponding pixel PX is disposed. For example, the first subpixel SPX1, the second subpixel SPX2 and the third subpixel SPX3 may be sequentially disposed along the first direction DR1, and at least one of the light emitting elements LE of each of the first subpixel SPX1 and the third subpixel SPX3 may be bonded at an angle on a first pixel electrode PXE1 and/or a third pixel electrode PXE3 to face the center of the unit pixel area UPA. The light emitting elements LE disposed in the second subpixel SPX2 located at the center of the unit pixel area UPA may be bonded to face the top of the pixel PX.

For example, the first light emitting element LE1 and the second light emitting element LE2 of the first subpixel SPX1 may be bonded at an angle on the first pixel electrode PXE1 to face the center of the unit pixel area UPA. In one or more embodiments, a bonding electrode BDE of each of the first light emitting element LE1 and the second light emitting element LE2 of the first subpixel SPX1 may be disposed more on a portion (e.g., a left portion) of a lower surface of a body portion CBD that is close to the periphery of the unit pixel area UPA.

Similarly, the first light emitting element LE1 and the second light emitting element LE2 of the third subpixel SPX3 may be bonded at an angle on the third pixel electrode PXE3 to face the center of the unit pixel area UPA. In one or more embodiments, a bonding electrode BDE of each of the first light emitting element LE1 and the second light emitting element LE2 of the third subpixel SPX3 may be disposed more on a portion (e.g., a right portion) of a lower surface of a body portion CBD which is close to the periphery of the unit pixel area UPA.

On the other hand, in the second subpixel SPX2 located at the center of the unit pixel area UPA compared with the first subpixel SPX1 and the third subpixel SPX3, the first light emitting element LE1 and the second light emitting element LE2 may be bonded substantially perpendicularly on a second pixel electrode PXE2. For example, light output surfaces of the first light emitting element LE1 and the second light emitting element LE2 of the second subpixel SPX2 (e.g., light output surfaces of a first body portion CBD1 and a second body portion CBD2) may face the top of the second subpixel SPX2. In one or more embodiments, a bonding electrode BDE of each of the first light emitting element LE1 and the second light emitting element LE2 of the second subpixel SPX2 may be disposed substantially on a central portion of a lower surface of a body portion CBD.

Because the light emitting elements LE of the subpixels SPX are disposed to face the center of the unit pixel area UPA, light emitted from the subpixels SPX1 through SPX3 may be more concentrated to the center of the pixel PX. Accordingly, light interference that may occur between adjacent pixels PX can be reduced, and a desired gray level or color to be expressed in each pixel PX can be expressed more accurately.

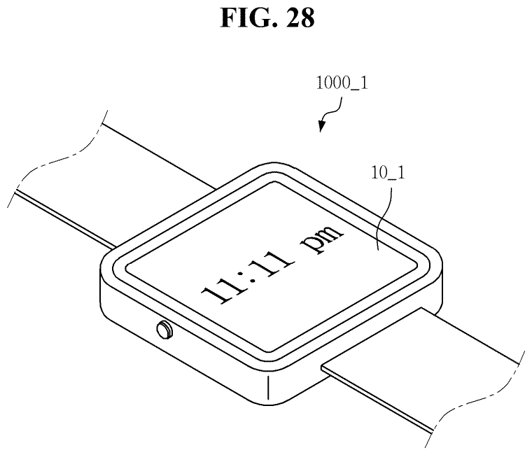

FIG. 28 is an example view of a smart watch including a display device according to one or more embodiments. Referring to FIG. 28, a display device 10_1 according to one or more embodiments may be applied to a smart watch 1000_1 which is one of smart devices.

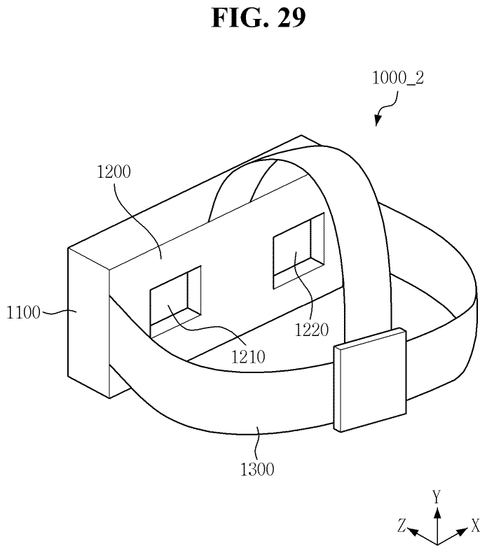

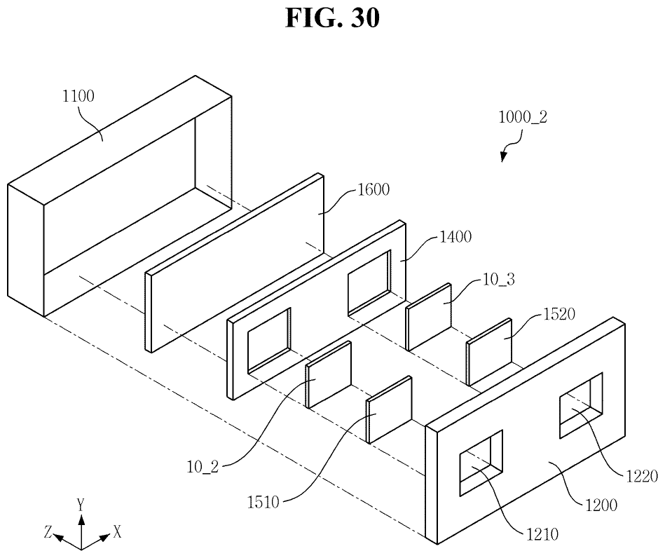

FIGS. 29 and 30 are example views of a virtual reality (VR) device including a display device according to one or more embodiments.

Referring to FIGS. 29 and 30, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220.

Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame

1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 29 and 30, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

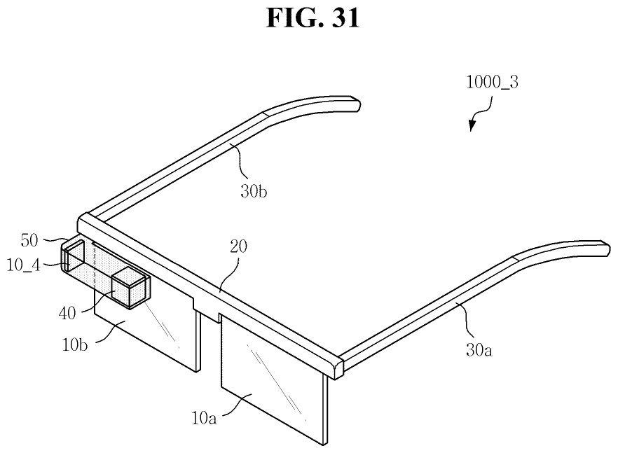

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 31 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus

(USB) terminal, a display port, or a high-definition multimedia interface (HDMI) terminal, and the wireless communication module may be a 5G communication module, a 4G communication module, a Wi-Fi module, and/or a Bluetooth module.

FIG. 31 is an example view of a VR device including a display device according to one or more embodiments. FIG. 31 illustrates a VR device 1000_3 to which a display device 10_4 according to one or more embodiments has been applied.

Referring to FIG. 31, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 31, a case where the VR device 1000_3 is a glasses-type display device including the eyeglass frame legs 30a and 30b is illustrated as an example. That is, the VR device 1000_3 according to the embodiment is not limited to the one illustrated in FIG. 31 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 31, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

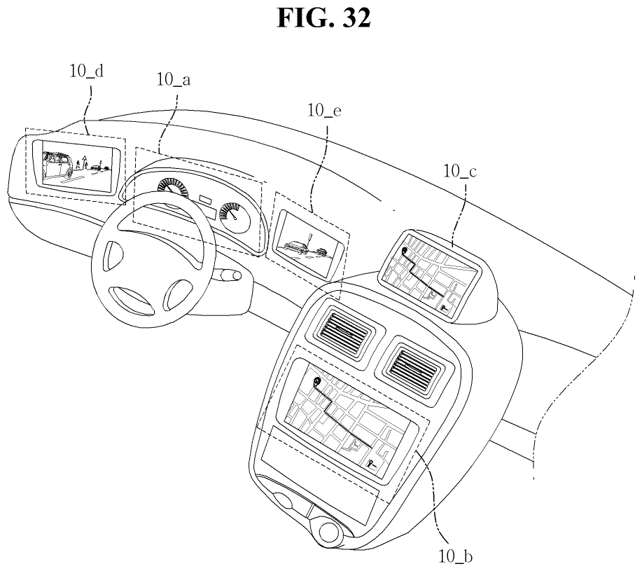

FIG. 32 is an example view illustrating a vehicle instrument cluster and center fascia including display devices according to one or more embodiments. FIG. 32 illustrates a vehicle to which display devices 10_a through 10_e according to one or more embodiments have been applied.

Referring to FIG. 32, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

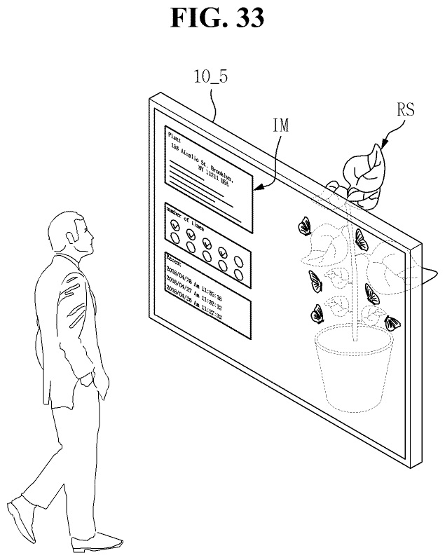

FIG. 33 is an example view of a transparent display device including a display device according to one or more embodiments.

Referring to FIG. 33, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

what is claimed is:

1. A display device comprising a pixel comprising a first subpixel, wherein the first subpixel comprises:
a first pixel electrode; and
a first light emitting element and a second light emitting element on the first pixel electrode, each of the first light emitting element and the second light emitting element comprising a body portion and a bonding electrode at a first surface of the body portion, the body portion comprising a first semiconductor layer, an active layer, and a second semiconductor layer,
wherein at least one of the first light emitting element or the second light emitting element is disposed at an angle on the first pixel electrode.

2. The display device of claim 1, wherein each of the first light emitting element and the second light emitting element comprises a light output surface corresponding to a second surface of the body portion.

3. The display device of claim 2, wherein the light output surfaces of the first light emitting element and the second light emitting element are tilted toward a center of the first subpixel.

4. The display device of claim 3, wherein the bonding electrode of each of the first light emitting element and the second light emitting element is located more on a portion of the first surface of the body portion which is close to a periphery of the first subpixel.

5. The display device of claim 2, further comprising:
a light blocking layer around an emission area where the first light emitting element and the second light emitting element are located; and
a reflective layer on the light blocking layer.

6. The display device of claim 5, wherein the light output surfaces of the first light emitting element and the second light emitting element are tilted toward a periphery of the first subpixel.

7. The display device of claim 6, wherein the bonding electrode of each of the first light emitting element and the second light emitting element is located more on a portion of the first surface of the body portion that is close to a center of the first subpixel.

8. The display device of claim 1, wherein at least one of the bonding electrodes of the first light emitting element or the second light emitting element has a thickness that gradually changes as a distance to a center or a periphery of the first subpixel decreases.

9. The display device of claim 1, wherein at least one of the body portions of the first light emitting element or the second light emitting element is tilted with respect to the first pixel electrode and contacts the first pixel electrode.

10. The display device of claim 1, wherein the bonding electrode of each of the first light emitting element and the second light emitting element is on the entire first surface of the body portion.

11. The display device of claim 1, wherein the first subpixel further comprises a third light emitting element on the first pixel electrode and between the first light emitting element and the second light emitting element.

12. The display device of claim 11, wherein the third light emitting element comprises a body portion and a bonding electrode at a first surface of the body portion, the third light emitting element being on and perpendicular to the first pixel electrode, the body portion comprising a first semiconductor layer, an active layer, and a second semiconductor layer.

13. The display device of claim 12, wherein the third light emitting element comprises a light output surface corresponding to a second surface of the body portion, and the light output surface of the third light emitting element faces top of the first subpixel.

14. The display device of claim 1, wherein the first subpixel further comprises a first light conversion layer on the first light emitting element and the second light emitting element.

15. The display device of claim 14, wherein the first light conversion layer comprises first wavelength conversion particles to convert light emitted from the first light emitting element and the second light emitting element into light of another color.

16. The display device of claim 14, wherein a second surface of the first light conversion layer comprises a lens-shaped curved surface.

17. The display device of claim 1, wherein each of the first light emitting element and the second light emitting element further comprises a first reflective layer between the body portion and the bonding electrode.

18. The display device of claim 17, wherein each of the first light emitting element and the second light emitting element further comprises a second reflective layer covering side surfaces of the first semiconductor layer, the active layer, and the second semiconductor layer.

19. The display device of claim 1, wherein the pixel further comprises a second subpixel and a third subpixel, the second subpixel comprising a second pixel electrode and at least one light emitting element on the second pixel electrode, and the third subpixel comprising a third pixel electrode and at least one light emitting element on the third pixel electrode, the first subpixel, the second subpixel, and the third subpixel being sequentially located along a first direction.

20. The display device of claim 19, wherein at least one of the first light emitting element or the second light emitting element of the first subpixel is disposed at an angle on the first pixel electrode to face a center of a unit pixel area where the pixel is located, and the at least one light emitting element of the third subpixel is located at an angle on the third pixel electrode to face the center of the unit pixel area.

21. An electronic device for providing an image, comprising:
a display device comprising a pixel comprising a first subpixel, wherein the first subpixel comprises:
a first pixel electrode; and
a first light emitting element and a second light emitting element on the first pixel electrode, each of the first light emitting element and the second light emitting element comprising a body portion and a bonding electrode at a first surface of the body portion, the body portion comprising a first semiconductor layer, an active layer, and a second semiconductor layer,
wherein at least one of the first light emitting element or the second light emitting element is disposed at an angle on the first pixel electrode.
